(19) United States
(12) Patent Application Publication
(10) Pub. No.: US 2026/0040805 A1
(43) Pub. Date: Feb. 5, 2026

(54) BONDING DEVICE AND, ELECTRONIC DEVICE AND METHOD FOR BONDING DISPLAY DEVICE

(71) Applicants: Samsung Display Co., LTD., Yongin-si (KR); ULVAC, INC., Kanagawa (JP)

(72) Inventors: Kyung Hoon CHUNG, Yongin-si (KR); Kazuhiko KOIZUMI, Kanagawa (JP); Junichiro KOIKE, Kanagawa (JP); Shinjiro KURAHASHI, Kanagawa (JP); Jung Seob LEE, Yongin-si (KR); Yong Sic JEON, Yongin-si (KR); Hyeon Sik KIM, Yongin-si (KR); Yong YEO, Yongin-si (KR)

(21) Appl. No.: 19/211,591

(22) Filed: May 19, 2025

(30) Foreign Application Priority Data
Jul. 31, 2024 (KR) 10-2024-0101656

(51) Int. Cl. H10K 71/50

(52) U.S. Cl. CPC H10K 71/50

(57) ABSTRACT

A bonding device includes a transport unit, a carrier movable on and along the transport unit and having a substrate tray accommodated therein, a rotatable bonding stage disposed on the transport unit, a support disposed on the bonding stage and movable on the bonding stage along an upstream direction of the transport unit, a downstream direction of the transport unit, a downward direction toward the bonding stage, an upward direction opposite to the downward direction, a first rotation direction toward the upstream direction, and a second rotation direction toward the downstream direction and a gripper connected to the support so as to be disposed between the support and the bonding stage.

This application claims priority to Korean Patent Application No. 10-2024-0101656, filed on Jul. 31, 2024, and all the benefits accruing therefrom under 35 U.S.C. § 119, the content of which in its entirety is herein incorporated by reference.

### BACKGROUND

### 1. Field

The invention relates generally to a manufacturing device for a display device, and more particularly, to a bonding device, an electronic device and a method for bonding a display device, capable of preventing a damage of a substrate in addition to improving an alignment state of the substrate.

### 2. Description of the Related Art

Organic light emitting diode displays have self-luminous characteristics and, unlike liquid crystal displays, do not require a separate light source and thus can be reduced in thickness and weight. In addition, organic light emitting diode displays are attracting attention as next-generation displays for portable electronic devices due to their high-quality characteristics such as low power consumption, high luminance, and high response speed.

### SUMMARY

Aspects of the invention provide a bonding device, an electronic device and a method for bonding a display device, capable of preventing a damage of a substrate in addition to improving an alignment state of the substrate.

However, aspects of the invention are not restricted to those set forth herein. The aspects of the invention will become more apparent to one of ordinary skill in the art to which the invention pertains by referencing the detailed description of the invention given below.

According to an aspect, there is provided a bonding device for a display device. The bonding device includes a transport unit, a carrier movable on and along the transport unit and having a substrate tray accommodated therein, a rotatable bonding stage disposed on the transport unit, a support disposed on the bonding stage and movable on the bonding stage along an upstream direction of the transport unit, a downstream direction of the transport unit, a downward direction toward the bonding stage, an upward direction opposite to the downward direction, a first rotation direction toward the upstream direction, and a second rotation direction toward the downstream direction and a gripper connected to the support so as to be disposed between the support and the bonding stage.

According to another aspect, there is provided a bonding method for a display device. The bonding method includes preparing a bonding device for a display device, wherein the bonding device includes a transport unit, a carrier movable on and along the transport unit and having a substrate tray accommodated therein, a rotatable bonding stage disposed on the transport unit, a support disposed on the bonding stage and movable on the bonding stage along an upstream direction of the transport unit, a downstream direction of the transport unit, a downward direction toward the bonding stage, an upward direction opposite to the downward direction, a first rotation direction toward the upstream direction, and a second rotation direction toward the downstream direction, and a gripper connected to the support to be disposed between the support and the bonding stage, placing the carrier on the transport unit, placing the bonding stage to be directed parallel to the transport unit, placing a substrate on an upper surface of the bonding stage, supporting the first side of the substrate of the downstream direction by using the gripper, rotating the bonding stage so that an upper surface of the bonding stage faces the downstream direction, moving the support and the carrier to the downstream direction in a state where the substrate is supported by the gripper, moving the support so that the gripper is disposed adjacent to a first hole of the substrate tray and rotating the support in the second rotation direction in a state where the gripper is disposed adjacent to the first hole of the substrate tray.

According to an embodiment of a bonding device, an electronic device and a method for bonding a display device, damage of the substrate can be prevented, and an alignment of the substrate can be improved.

However, the effects of the invention are not restricted to those set forth herein. The above and other effects of the invention will become more apparent to one of ordinary skill in the art to which the invention pertains.

### BRIEF DESCRIPTION OF THE DRAWINGS

Aspects of the invention will become apparent and more readily appreciated from the following description of the embodiments, taken in conjunction with the accompanying drawings in which:

FIG. 1 is a schematic diagram of a deposition device, according to an embodiment;

FIG. 2 is a perspective view of a substrate tray of FIG. 1, according to an embodiment;

FIG. 3 is a perspective view of a carrier disposed on a transport track, according to an embodiment;

FIG. 4 illustrates a state where the substrate tray of FIG. 2 is coupled to the carrier of FIG. 3, according to an embodiment;

FIG. 5 is an exploded, perspective view of a bonding device for a display device, according to an embodiment;

FIG. 6 is a cross-sectional view of a support and a gripper of a bonding device for a display device, according to an embodiment;

FIG. 7 is a view for explaining a bonding method using a bonding device for a display device, according to an embodiment.

FIG. 8 is a view for explaining a bonding method using a bonding device for a display device, according to an embodiment.

FIG. 9 is a view for explaining a bonding method using a bonding device for a display device, according to an embodiment.

FIG. 10 is a view for explaining a bonding method using a bonding device for a display device, according to an embodiment.

FIG. 11 is a view for explaining a bonding method using a bonding device for a display device, according to an embodiment.

FIG. 12 is a view for explaining a bonding method using a bonding device for a display device, according to an embodiment.

FIG. 13 is a view for explaining a bonding method using a bonding device for a display device, according to an embodiment.

FIG. 14 is a view for explaining a bonding method using a bonding device for a display device, according to an embodiment.

FIG. 15 is a view for explaining a bonding method using a bonding device for a display device, according to an embodiment.

FIG. 16 is a view for explaining a bonding method using a bonding device for a display device, according to an embodiment.

FIG. 17 is a view for explaining a bonding method using a bonding device for a display device, according to an embodiment.

FIG. 18 is a view for explaining a bonding method using a bonding device for a display device, according to an embodiment.

FIG. 19 is a view for explaining a bonding method using a bonding device for a display device, according to an embodiment.

FIG. 20 is a view for explaining a bonding method using a bonding device for a display device, according to an embodiment.

FIG. 21 is a view for explaining a bonding method using a bonding device for a display device, according to an embodiment.

FIG. 22 is a view for explaining a bonding method using a bonding device for a display device, according to an embodiment.

FIG. 23 is a view for explaining a bonding method using a bonding device for a display device, according to an embodiment.

FIG. 24 is a view for explaining a bonding method using a bonding device for a display device, according to an embodiment.

FIG. 25 is a view for explaining a bonding method using a bonding device for a display device, according to an embodiment.

FIG. 26 is a view for explaining a bonding method using a bonding device for a display device, according to an embodiment.

FIG. 27 is a view for explaining a bonding method using a bonding device for a display device, according to an embodiment.

FIG. 28 is a view for explaining a bonding method using a bonding device for a display device, according to an embodiment.

FIG. 29 is a view for explaining a bonding method using a bonding device for a display device, according to an embodiment.

FIG. 30 is a view for explaining a bonding method using a bonding device for a display device, according to an embodiment.

FIG. 31 is a block diagram of an electronic device, according to an embodiment.

FIG. 32 is a graphical image of an electronic device, according to an embodiment.

FIG. 33 is a graphical image of an electronic device, according to an embodiment.

FIG. 34 is a graphical image of an electronic device, according to an embodiment.

### DETAILED DESCRIPTION

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the invention may be combined partially or totally. As will be clearly appreciated by those skilled in the art, technically various interactions and operations are possible. Various embodiments can be practiced individually or in combination.

Hereinafter, embodiments will be described in detail with reference to the accompanying drawings.

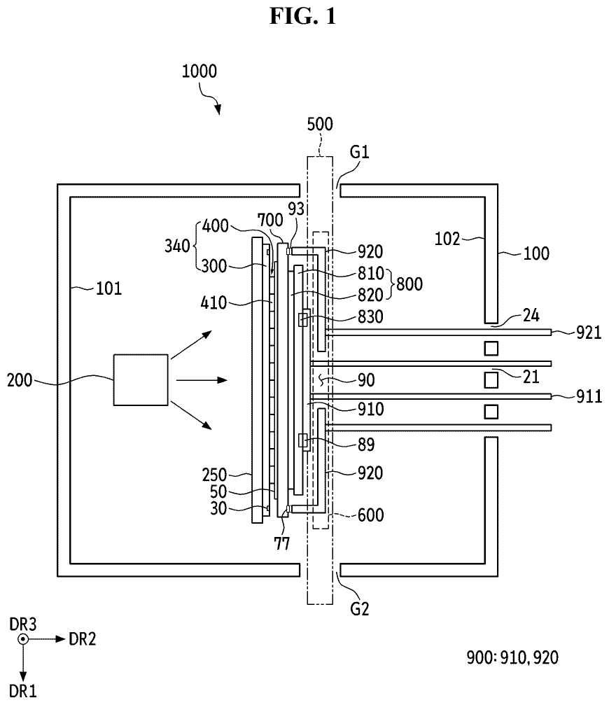

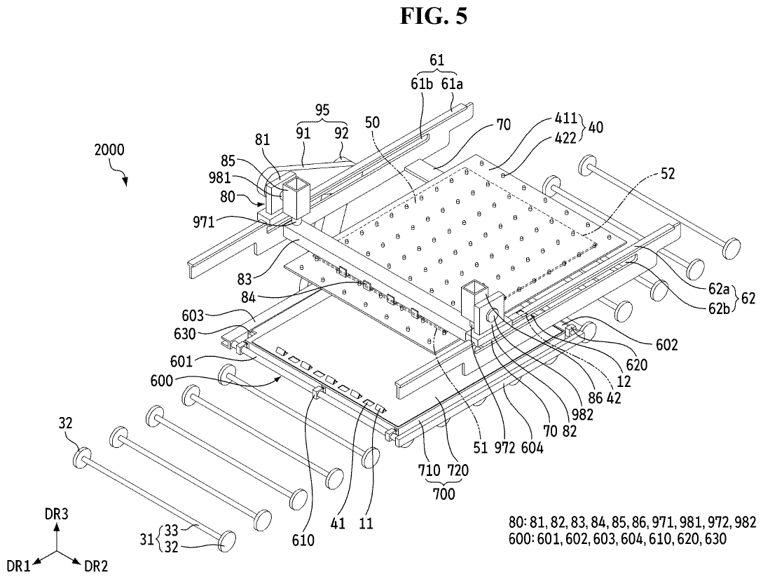

A manufacturing device for a display device, according to an embodiment, may include a deposition device 1000 of FIG. 1 (e.g., a deposition device for a substrate for a display device), a bonding device 2000 of FIG. 5 (e.g., a device for bonding a substrate for a display device from a substrate tray), and a position changing device (e.g., a device for changing the position of a carrier for manufacturing a display device).

FIG. 1 is a schematic diagram of a deposition device 1000, according to an embodiment. In FIG. 1, a reverse direction (hereinafter, referred to as a third reverse direction) of a third direction DR3 may be the direction of gravity.

In an embodiment and referring to FIG. 1, the deposition device 1000 for a display device may include a chamber 100, a deposition source 200, a deposition stage 250, a mask structure 340, a substrate tray 700, a magnet plate 800, a transport track 500, a carrier 600, and a driving mechanism 900.

In an embodiment, the chamber 100 may define a deposition space in which a deposition process is performed. A layer deposition process for manufacturing an organic light emitting diode display device may be performed inside the chamber 100. The chamber 100 may be a vacuum chamber 100. The deposition source 200, the deposition stage 250, the driving mechanism 900, and a portion of the transport track 500 described above may be disposed inside the chamber 100. When a deposition process is in progress, the deposition source 200, the deposition stage 250, the mask structure 340, a substrate 50, the substrate tray 700, the magnet plate 800, a portion of the transport track 500, and the driving mechanism 900 may be disposed inside the chamber 100.

In an embodiment, the deposition source 200 may be disposed inside the chamber 100. For example, the deposition source 200 may be disposed between a first inner wall 101 of the chamber 100 and the deposition stage 250. The deposition source 200 may provide a deposition material. The deposition material from the deposition source 200 may pass through an opening of the deposition stage 250 and move toward the mask structure 340. Specifically, the deposition source 200 may evaporate a deposition material such as an organic material or an electrode material by heating the deposition material to a high temperature, and the evaporated deposition material may be deposited on the substrate 50 through pattern holes of the mask structure 340. The organic material may be, for example, a material for manufacturing a hole injection layer, a hole transport layer, a light emitting layer, an electron transport layer, and an electron injection layer disposed between an anode and a cathode of an organic light emitting diode. The substrate 50 may be, for example, a substrate used in a display device including organic light emitting diodes.

In an embodiment, the deposition stage 250 may be disposed on the deposition source 200. For example, the deposition stage 250 may be disposed between the deposition source 200 and the mask structure 340. The deposition stage 250 may be disposed in a fixed state inside the chamber 100. The deposition stage 250 may be tilted toward the deposition source 200. For example, the deposition stage 250 may be tilted in a second reverse direction of a second direction DR2 with respect to the third direction DR3. Accordingly, an angle formed between a surface of the deposition stage 250 which faces the deposition source 200 and the ground (e.g., a bottom surface of the chamber 100) on which the deposition stage 250 is disposed may be an acute angle. Here, supports may be disposed on a lower side of the deposition stage 250 to protrude from a surface of the lower side along the second direction DR2. The deposition stage 250 may be shaped like a quadrangular frame with a penetrated central portion. For example, the deposition stage 250 may have an opening in the central portion.

In an embodiment, the mask structure 340 may be disposed on the deposition stage 250. For example, the mask structure 340 may be disposed between the deposition stage 250 and the substrate tray 700. The mask structure 340 may be disposed on the supports of the deposition stage 250. Here, since the deposition stage 250 is tilted, the mask structure 340 may also be tilted on the deposition stage 250. The mask structure 340 may include a frame 300 and a mask 400.

In an embodiment, the frame 300 may be disposed on the deposition stage 250. For example, the frame 300 may be disposed between the deposition stage 250 and the mask 400. The frame 300 may be shaped like a quadrangular frame with a penetrated central portion. For example, the frame 300 may have an opening in the central portion. Grooves 30 may be disposed at both edges of the frame 300, where the frame 300 may include a magnetic material. For example, the frame 300 may include a material (e.g., iron (Fe)) that can be attracted to a magnet.

In an embodiment, the mask 400 may be disposed on the frame 300. For example, the mask 400 may be disposed between the frame 300 and the substrate tray 700. The mask 400 may be disposed on the frame 300 to cover the opening of the frame 300. Edges of the mask 400 may be attached to the frame 300. For example, the mask 400 may be attached to the frame 300 by welding and may be a fine metal mask (FMM).

In an embodiment, the mask 400 may include a plurality of sub-masks 410 (or mask sticks). Each of the sub-masks 410 may have a rectangular shape extending in the third direction DR3. The sub-masks 410 may be arranged along a first direction DR1. Adjacent sub-masks 410 may contact each other. Each sub-mask 410 excluding both edges may be disposed on the opening 39 of the frame 300. Although not illustrated, each sub-mask 410 may have a plurality of pattern holes penetrating the sub-mask 410 in the second direction DR2. A deposition material from the deposition source 200 may be deposited on the substrate 50 through the pattern holes of each sub-mask 410. Each sub-mask 410 may be made of a material including a magnetic material (e.g., iron (Fe)). For example, each sub-mask 410 may include a material that is attracted to a magnet.

In an embodiment, the substrate tray 700 may be disposed on the mask structure 340. For example, the substrate tray 700 may be disposed between the mask 400 of the mask structure 340 and the magnet plate 800. The substrate tray 700 may transport the substrate 50. Here, the substrate tray 700 may adsorb the substrate 50 using an electrostatic force. For example, the substrate tray 700 may provide a surface on which the substrate 50 is placed while serving as an electrostatic chuck which adsorbs and fixes the substrate 50 to the surface of the substrate tray 700. The substrate tray 700 may be made of a material including ceramic or titanium.

In an embodiment, the magnet plate 800 may be disposed on the substrate tray 700. For example, the magnet plate 800 may be disposed between the substrate tray 700 and the driving mechanism 900. The magnet plate 800 may be disposed on the substrate tray 700 to face the substrate tray 700. The magnet plate 800 may provide a magnetic force. For example, the magnet plate 800 may provide a magnetic force so that the metal mask 400 described above is closely attached to the substrate 50.

In an embodiment, the magnet plate 800 may include a base member 810 and a plurality of magnets 820 disposed on the base member 810. For example, the magnets 820 may be disposed on the base member 810. As a specific example, when a side surface of the base member 810 which faces the substrate tray 700 is defined as a first surface, the magnets 820 may be disposed on the first surface of the base member 810. Each magnet 820 may include, for example, a permanent magnet.

In an embodiment, each of the magnets 820 may have an N pole and an S pole. A plurality of magnets 820 disposed along the first direction DR1 may be disposed such that opposite polarities face each other in the first direction DR1. A plurality of magnets 820 disposed along the second direction DR2 may be disposed such that opposite polarities face each other.

In an embodiment, when a surface opposite the first surface of the base member 810 is defined as a second surface of the base member 810, a plurality of magnetic objects 830 may be disposed on the second surface of the base member 810. For example, the magnetic objects 830 may be disposed on the second surface in coupling grooves of the base member 810. For example, the magnetic objects 830 may include a material (e.g., iron (Fe)) that can be attracted to a magnet.

In an embodiment, the driving mechanism 900 may include a first driving mechanism 910 and a second driving mechanism 920.

In an embodiment, the first driving mechanism 910 may be disposed between the magnet plate 800 and the second driving mechanism 920. For example, the first driving mechanism 910 may be disposed between the base member 810 of the magnet plate 800 and the second driving mechanism 920. The first driving mechanism 910 may include magnets 89. For example, the magnets 89 may be disposed on a surface opposite a surface of the first driving mechanism 910 which is connected to a first driving shaft 911. The magnets 89 of the first driving mechanism 910 may correspond to (or overlap) the magnetic objects 830 of the magnet plate 800. The magnets 89 may include permanent magnets.

In an embodiment, the magnet plate 800 may be detachably attached to the first driving mechanism 910. For example, the base member 810 of the magnet plate 800 may be detachably attached to the magnets 89 of the first driving mechanism 910. In other words, the magnetic objects 830 of the base member 810 may be attached to the magnets 89 of the first driving mechanism 910 by a magnetic force from the magnets 89 of the first driving mechanism 910. The first driving mechanism 910 may move toward the deposition source 200 or in the opposite direction within the chamber 100. For example, the first driving mechanism 910 may move along the second reverse direction or the second direction DR2. To this end, according to an embodiment, the first driving mechanism 910 may be connected to the first driving shaft 911 which is extended along the second reverse direction or retracted along the second direction DR2. The first driving shaft 911 may be connected to an external driver through a hole 90 of the second driving mechanism 920 and a hole 21 of the chamber 100. In addition, the first driving mechanism 910 may move further in the first direction DR1, a first reverse direction, the third direction DR3, or the third reverse direction. In this case, the first driving shaft 911 may move further in the first direction DR1, the first reverse direction, the third direction DR3, or the third reverse direction. The movement of the magnet plate 800 attached to the first driving mechanism 910 may be controlled by the movement of the first driving mechanism 910.

In an embodiment, the second driving mechanism 920 may be disposed between the first driving mechanism 910 and a second inner wall 102 of the chamber 100. The second driving mechanism 920 may include electro-permanent magnets 93. The substrate tray 700 may be attached to the second driving mechanism 920. For example, the substrate tray 700 may be attached to the second driving mechanism 920 as magnetic objects 77 of the substrate tray 700 are attached to the electro-permanent magnets 93 of the second driving mechanism 920. The electro-permanent magnets 93 may be disposed at both edges of the second driving mechanism 920. The magnetic objects 77 may be disposed at both edges of the substrate tray 700 to correspond to the electro-permanent magnets 93. The magnetic objects 77 may include a magnetic material that is attracted to a magnet, such as iron (Fe).

In an embodiment, the second driving mechanism 920 may also include electromagnets instead of the electro-permanent magnets 93. The second driving mechanism 920 may move toward the deposition source 200 or in the opposite direction within the chamber 100. For example, the second driving mechanism 920 may move along the second reverse direction or the second direction DR2. To this end, according to an embodiment, the second driving mechanism 920 may be connected to a second driving shaft 921 which is extended along the second reverse direction or retracted along the second direction DR2. In addition, the second driving mechanism 920 may move further in the first direction DR1, the first reverse direction, the third direction DR3, or the third reverse direction. In this case, the second driving shaft 921 may move further in the first direction DR1, the first reverse direction, the third direction DR3, or the third reverse direction. The movement of the substrate tray 700 attached to the second driving mechanism 920 may be controlled by the movement of the second driving mechanism 920. The second driving mechanism 920 may perform an alignment operation between the substrate 50 of the substrate tray 700 and the mask structure 340 by controlling the position of the substrate tray 700 attached to the second driving mechanism 920.

In an embodiment, the transport track 500 may be, for example, disposed inside the chamber 100 and outside the chamber 100 to pass through a first gate G1 and a second gate G2 of the chamber 100. The transport track 500 may extend along the first direction DR1. The first gate G1 and the second gate G2 may face each other.

In an embodiment, the carrier 600 may move along the transport track 500. For example, the carrier 600 may move along the transport track 500 in a magnetic levitation manner. The carrier 600 may transport the substrate tray 700.

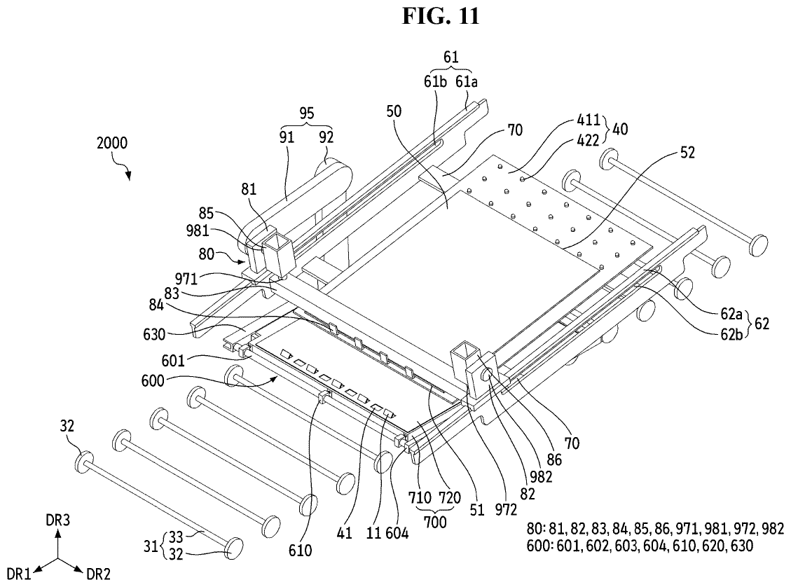

In an embodiment and as described above, an upper side of the deposition stage 250 may be tilted toward the deposition source 200 (e.g., tilted at the same angle as the carrier 600 illustrated in FIG. 11 to be described later). Accordingly, the mask structure 340, the substrate tray 700, the substrate 50, the magnet plate 800, the first driving mechanism 910, the second driving mechanism 920, the transport track 500, and the carrier 600 described above may also be tilted at the same angle as the deposition stage 250. Accordingly, particles generated during a deposition process on the substrate 50 may fall in the direction of gravity without sticking to the substrate 50. Therefore, the substrate 50 can be prevented from being contaminated by the particles.

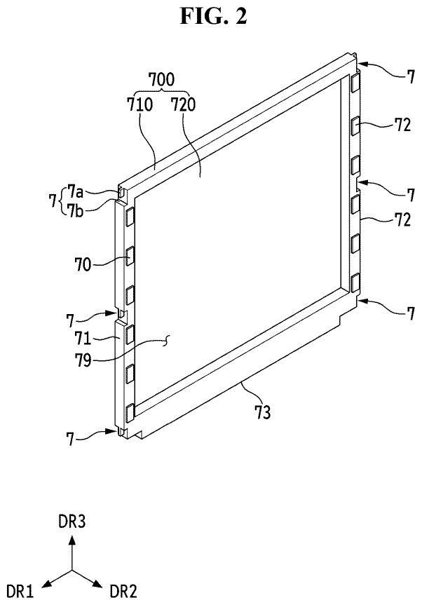

FIG. 2 is a perspective view of the substrate tray 700 of FIG. 1, according to an embodiment.

In an embodiment and as illustrated in FIG. 2, the substrate tray 700 may include a support plate 710 and an electrostatic chuck 720.

In an embodiment, the support plate 710 may be shaped like a quadrangular frame with a penetrated central portion. For example, the support plate 710 may have an opening 79 in the central portion.

In an embodiment, the electrostatic chuck 720 may be disposed on the support plate 710. For example, the electrostatic chuck 720 may be disposed between the support plate 710 and the substrate 50. Here, the electrostatic chuck 720 may cover the opening 79 of the support plate 710. The substrate 50 may be placed on the electrostatic chuck 720 and the electrostatic chuck 720 may adsorb the substrate 50 using an electrostatic force.

In an embodiment, at least one detachable member 7 may be disposed at the edges of the substrate tray 700. For example, a detachable member 7 may be disposed near each corner of the quadrangular support plate 710. Specifically, the support plate 710 may have six detachable members 7. Here, three of the six detachable members 7 may be disposed at the top, middle and bottom of a first side 71 of the substrate tray 700, respectively, and the remaining three detachable members 7 may be disposed at the top, middle and bottom of a second side 72 of the substrate tray 700, respectively. The first side 71 and the second side 72 of the substrate tray 700 may face each other along the first direction DR1.

In an embodiment, each detachable member 7 may include a coupling tip 7a and a separation groove 7b disposed adjacent to each other in the third direction DR3 The coupling tip 7a may be disposed higher than the separation groove 7b. For example, in one detachable member 7, the coupling tip 7a may be disposed higher than the separation groove 7b in the third direction DR3. The coupling tip 7a may have a smaller thickness (e.g., size in the second direction DR2) than other parts of the substrate tray 700. For example, the coupling tip 7a may have a smaller thickness (e.g., size in the second direction DR2) than other parts of the support plate 710. The separation groove 7b may be recessed from the first side 71 of the substrate tray 700 (e.g., the support plate 710) toward the second side 72 or may be recessed from the second side 72 toward the first side 71. For example, separation grooves 7b disposed on different sides and facing each other may be recessed toward each other.

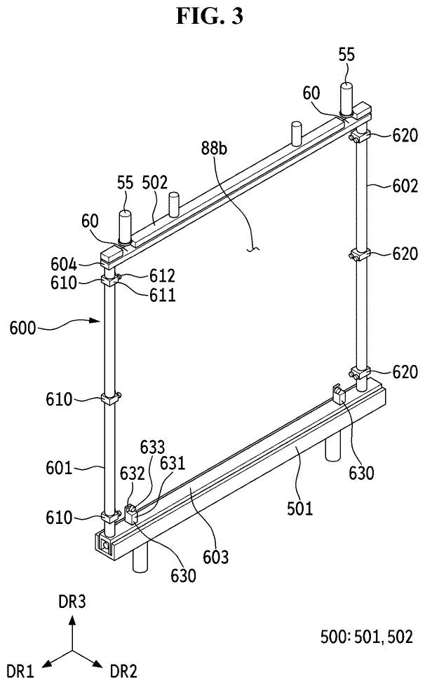

FIG. 3 is a perspective view of a carrier disposed on a transport track, according to an embodiment. Here, FIG. 3 may be a perspective view of the carrier 600 disposed on the transport track 500 of FIG. 1.

In an embodiment, the carrier 600 may move along the transport track 500. The transport track 500 may include a lower track 501 and an upper track 502 facing each other in the third direction DR3. Therefore, the carrier 600 may be disposed between the lower track 501 and the upper track 502. The carrier 600 may move along the transport track 500 between the lower track 501 and the upper track 502.

In an embodiment, the carrier 600 may be shaped like a quadrangular frame as in the example illustrated in FIG. 3. However, the shape of the carrier 600 is not limited thereto and can be changed to various shapes.

In an embodiment, the carrier 600 may include a plurality of bars 601, 602, 603 and 604 and a plurality of support members 610, 620 and 630 as illustrated in FIG. 3. For example, the carrier 600 may include a first bar 601, a second bar 602, a third bar 603, and a fourth bar 604 connected to each other. The substrate tray 700 may be placed in an area (e.g., an opening 88b) surrounded and defined by the first bar 601, the second bar 602, the third bar 603, and the fourth bar 604.

In an embodiment, the first bar 601 and the second bar 602 may face each other in the first direction DR1. The third bar 603 and the fourth bar 604 may face each other in the third direction DR3. The first bar 601 may be disposed between an end of the third bar 603 and an end of the fourth bar 604. The second bar 602 may be disposed between the other end of the third bar 603 and the other end of the fourth bar 604.

In an embodiment, the support members 610, 620 and 630 may include one or more first support members 610 extending from the first bar 601, one or more second support members 620 extending from the second bar 602, and one or more third support members 630 extending from the third bar 603.

In an embodiment, each of the first support members 610 may include an extension portion 611 and a plurality of protrusions 612. A side of the extension portion 611 may be connected to the first bar 601. The extension portion 611 may extend from the first bar 601 toward the second bar 602. The protrusions 612 (e.g., two protrusions 612) may be disposed on the other side of the extension portion 611. The protrusions 612 may be rotatably connected to the other side of the extension portion 611. For example, each of the protrusions 612 may rotate about an axis parallel to the first direction DR1. The protrusions 612 may face each other in the second direction DR2. Each of the protrusions 612 may have a cylindrical shape. However, the shape of the protrusions 612 is not limited thereto and can be changed to various shapes.

In an embodiment, the second support members 620 may have the same configuration as the first support members 610 described above. However, an extension portion of each of the second support members 620 may extend from the second bar 602 toward the first bar 601.

In an embodiment, each of the third support members 630 may include an extension portion 631, a protruding portion 632, and a protrusion 633 and a side of the extension portion 631 may be connected to the third bar 603. The extension portion 631 may extend from the third bar 603 toward the fourth bar 604. The protruding portion 632 may be disposed on the other side of the extension portion 631. The protrusion 633 may be disposed on a side of the protruding portion 632. The protrusion 633 may be rotatably connected to the side of the protruding portion 632. For example, the protrusion 633 may rotate about an axis parallel to the second direction DR2. The protrusion 633 may have a cylindrical shape. However, the shape of the protrusion 633 is not limited thereto and can be changed to various shapes.

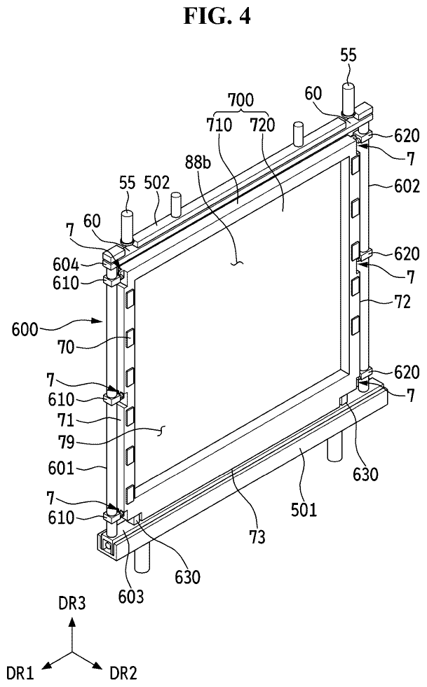

FIG. 4 illustrates a state where the substrate tray 700 of FIG. 2 is coupled to the carrier 600 of FIG. 3, according to an embodiment.

In an embodiment and as illustrated in FIG. 4, the first support members 610, the second support members 620, and the third support members 630 may support the substrate tray 700.

In an embodiment, each of the first support members 610 may support the first side 71 of the substrate tray 700. For example, the first side 71 of the substrate tray 700 may be placed and supported between the protrusions 612 of each first support member 610. Specifically, the first side 71 may be supported as a coupling tip 7a of the first side 71 is placed between the protrusions 612 of each first support member 610.

In an embodiment, each of the second support members 620 may support the second side 72 of the substrate tray 700. For example, the second side 72 of the substrate tray 700 may be placed and supported between protrusions of each second support member 620. Specifically, the second side 72 may be supported as a coupling tip 7a of the second side 72 is placed between the protrusions of each second support member 620.

In an embodiment, each of the third support members 630 may support a third side 73 of the substrate tray 700. For example, the third side 73 of the substrate tray 700 may be placed and supported on the protrusion 633 of each third support member 630. Here, the protrusion 633 of each third support member 630 may contact the third side 73.

In an embodiment, the deposition device 1000 may further include pushers 55, where the pushers 55 may be disposed on the carrier 600. For example, the pushers 55 may be disposed on the fourth bar 604 of the carrier 600. Specifically, the pushers 55 may face the fourth bar 604 through openings 60 of the upper track 502. The pushers 55 and the openings 60 of the upper track 502 may be disposed inside the chamber 100.

In an embodiment, the pushers 55 may move toward the fourth bar 604 or in the opposite direction. For example, the pushers 55 may move along the third reverse direction or the third direction DR3. The pushers 55 may move a distance of a first stage and a distance of a second stage along the third reverse direction. Here, the distance of the second stage may be greater than the distance of the first stage. Here, when the pushers 55 descend the distance of the second stage along the third reverse direction, the lower track 501 may also descend along the third reverse direction. For example, when the pushers 55 descend the distance of the second stage, the pushers 55 and the lower track 501 may descend together in the same direction.

In an embodiment, when the pushers 55 descend the distance of the first stage along the third reverse direction, they may contact the carrier 600. The carrier 600 may be lowered along the third reverse direction by the pressure of the pushers 55. At this time, since the lower track 501 remains as it is without being lowered, a gap between the carrier 600 and the lower track 501 may be reduced. Accordingly, the carrier 600 can be stably placed on the lower track 501 within the chamber 100. Here, when the pushers 55 descend the distance of the first stage, the descending distance is short. Therefore, even if the carrier 600 is lowered by the pressure of the pushers 55, the substrate tray 700 accommodated in the carrier 600 may be kept supported by the support members 610, 620 and 630 of the carrier 600.

In an embodiment, when the pushers 55 descend the distance of the second stage, the lower track 501 may also descend along the third reverse direction at the same time as the pushers 55. In other words, the pushers 55 and the lower track 501 may simultaneously descend along the third reverse direction. Accordingly, the carrier 600 and the lower track 501 may descend along the third reverse direction. At this time, the gap between the carrier 600 and the lower track 501 may be substantially equal to the gap between the carrier 600 and the lower track 501 when the pushers 55 descend the distance of the first stage described above. Accordingly, the first support members 610, the second support members 620, and the third support members 630 may be moved in the third reverse direction. Therefore, the protrusions 612 of each first support member 610 and the protrusions of each second support member 620 may be placed to face each other through the separation grooves 7b of the substrate tray 700. In other words, the protrusions 612 of each first support member 610 and a corresponding coupling tip 7a of the first side 71 of the substrate tray 700 do not contact each other, and the protrusions 612 of each second support member 620 and a corresponding coupling tip of the second side 72 of the substrate tray 700 do not contact each other.

In addition, in an embodiment, as the carrier 600 is lowered along the third reverse direction by the pushers 55 as described above, the third support members 630 and the substrate tray 700 may be separated from each other. For example, since the protrusions 612 of the second support members 620 and the third side 73 of the substrate tray 700 are separated from each other, the protrusions 633 of the third support members 630 and the third side 73 do not contact each other. Accordingly, the substrate tray 700 is no longer supported by the carrier 600. Therefore, the substrate tray 700 can easily move in the second direction DR2 and the second reverse direction without being interfered with by the carrier 600.

In an embodiment, the substrate tray 700 and the substrate 50 described above may be provided from the bonding device 2000. For example, the substrate tray 700 and the substrate 50 from the bonding device 2000 may be provided to the deposition device 1000 described above through a position changing device.

Hereinafter, the bonding device 2000, according to an embodiment, will now be described in detail as follows.

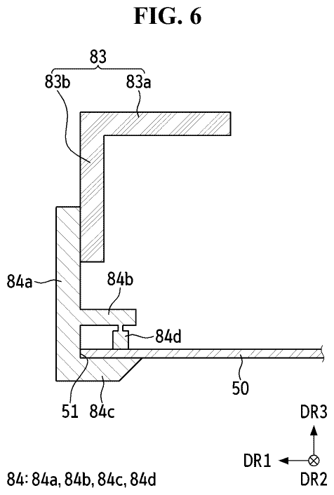

FIG. 5 is a perspective view of a bonding device 2000 for a display device, according to an embodiment. FIG. 6 is a cross-sectional view of a support 83 and a gripper 84 of a bonding device 2000 for a display device, according to an embodiment. For example, the support 83 and the gripper 84 of FIG. 6 may correspond to a support 83 and a gripper 84 of FIG. 5, respectively.

In an embodiment, the bonding device 2000 for a display device according to the embodiment may include, as illustrated in FIGS. 5 and 6, a transport unit 31, a bonding stage 40, a movable object 80, a first driving arm 95, a first guide bar 61, a second guide bar 62, and a plurality of support bars 70.

In an embodiment, the substrate tray 700 may further include a plurality of first clamps 11 and a plurality of first holes 41 disposed at an edge of the support plate 710 and a plurality of second clamps 12 and a plurality of second holes 42 disposed at the other edge of the support plate 710 as illustrated in FIG. 5. The first clamps 11 and the first holes 41 may be disposed adjacent to the first bar 601 of the carrier 600. The second clamps 12 and the second holes 42 may be disposed adjacent to the second bar 602 of the carrier 600. The first clamps 11 and the first holes 41 may be alternately disposed along the second direction DR2. The second clamps 12 and the second holes 42 may be alternately disposed along the second direction DR2. The first clamps 11, the first holes 41, the second clamps 12, and the second holes 42 may be exposed to the outside through through-holes penetrating the electrostatic chuck 720. The first holes 41 and the second holes 42 may be disposed to correspond to grippers 84 which will be described later.

In an embodiment, the transport unit 31 may be disposed along the first direction DR1 and may transport the carrier 600 along the first direction DR1. The transport unit 31 may include pairs of rollers 32 and a connecting shaft 33 connecting each pair of the rollers 32. The connecting shaft 33 may extend along the second direction DR2. Each pair of the rollers 32 may be connected to a side and the other side of the connecting shaft 33, respectively. Each pair of the rollers 32 may be rotatably connected to the connecting shaft 33, respectively.

In an embodiment, the first guide bar 61 and the second guide bar 62 may face each other. For example, the first guide bar 61 and the second guide bar 62 may face each other in the second direction DR2.

In an embodiment, the first guide bar 61 may include a first rail 61a and a first opening 61b. The first rail 61a may be disposed on the first guide bar 61 along an extending direction (or a longitudinal direction; e.g., the first direction DR1) of the first guide bar 61. The first opening 61b may penetrate the first guide bar 61. The first opening 61b may extend along the first rail 61a. The substrate 50 may be loaded into the bonding device 2000 from the outside through the first opening 61b or may be unloaded from the bonding device 2000 to the outside through the first opening 61b.

In an embodiment, the second guide bar 62 may include a second rail 62a and a second opening 62b, where the second rail 62a may be disposed on the second guide bar 62 along an extending direction (or a longitudinal direction; e.g., the first direction DR1) of the second guide bar 62. The second opening 62b may penetrate the second guide bar 62. The second opening 62b may extend along the second rail 62a. The substrate 50 may be loaded into the bonding device 2000 from the outside through the second opening 62b or may be unloaded from the bonding device 2000 to the outside through the second opening 62b.

In an embodiment, the support bars 70 may be disposed between the first guide bar 61 and the second guide bar 62. FIG. 2 illustrates an example in which two support bars 70 are spaced apart from each other in the first direction DR1. Each of the support bars 70 may be disposed parallel to the connecting shaft 33 of the transport unit 31 and may extend in the second direction DR2. The support bars 70 may connect the first guide bar 61 and the second guide bar 62 to each other. For example, an end of each of the support bars 70 may be connected to an inner surface of the first guide bar 61, and the other end of each of the support bars 70 may be connected to an inner surface of the second guide bar 62.

In an embodiment, the bonding stage 40 may be disposed on the support bars 70. For example, the bonding stage 40 may be disposed on the support bars 70 between the first guide bar 61 and the second guide bar 62 and may be connected to the support bars 70. The bonding stage 40 may include a base plate 411 and a plurality of support pins 422.

In an embodiment, the base plate 411 of the bonding stage 40 may be disposed on the support bars 70. The base plate 411 may be connected to the support bars 70. The support pins 422 of the bonding stage 40 may be disposed on the base plate 411. The support pins 422 may be shaped like pillars protruding upward from the base plate 411. The support pins 422 may be coupled to the base plate 411. For example, an end of each support pin 422 may be coupled to the base plate 411. A spherical ball rotatably connected to each support pin 422 may be disposed at the other end of the support pin 422. The support pins 422 may be arranged in a matrix form on the base plate 411.

In an embodiment, the movable object 80 may be disposed on the bonding stage 40. For example, the movable object 80 may be disposed on the bonding stage 40 to overlap the bonding stage 40. The movable object 80 may be movably coupled to the first guide bar 61 and the second guide bar 62. The movable object 80 may be disposed between the first guide bar 61 and the second guide bar 62 and may move along the first rail 61a of the first guide bar 61 and the second rail 62a of the second guide bar 62. For example, the movable object 80 may move on the bonding stage 40 along the first direction DR1 or the first reverse direction while being guided by the first rail 61a and the second rail 62a. The movable object 80 may include the support 83, a first driver 85, a second driver 86, a first coupling portion 81, a second coupling portion 82, and the grippers 84.

In an embodiment, the support 83 of the movable object 80 may be disposed between the first guide bar 61 and the second guide bar 62 and may extend along the second direction DR2. The support 83 may be disposed on the bonding stage 40 to overlap the bonding stage 40. The support 83 may have an “r”-shaped cross section.

According to an embodiment and as illustrated in FIG. 6, the support 83 may include a horizontal portion 83a and a vertical portion 83b. The vertical portion 83b may extend downward from a side of the horizontal portion 83a. For example, the vertical portion 83b may extend from a side of the horizontal portion 83a along the third reverse direction.

In an embodiment, the grippers 84 of the movable object 80 may be disposed on the support 83. The grippers 84 may be disposed on a lower side of the support 83. The grippers 84 may be arranged in a row along the support 83 in the second direction DR2 between the first guide bar 61 and the second guide bar 62. In other words, the grippers 84 may be disposed under the support 83 along the extending direction (e.g., the second direction DR2) of the support 83. The grippers 84 may be coupled to and supported by the support 83. The grippers 84 may have an “L” shaped cross section.

According to an embodiment, a gripper 84 may include a coupling portion 84a, a first extension portion 84c, a second extension portion 84b, and a pressing portion 84d.

In an embodiment, the coupling portion 84a of the gripper 84 may be connected to the vertical portion 83b of the support 83.

In an embodiment, the first extension portion 84c of the gripper 84 may extend along the first reverse direction from an edge of the coupling portion 84a.

In an embodiment, the second extension portion 84b of the gripper 84 may be disposed on the first extension portion 84c. For example, the second extension portion 84b may be disposed between the first extension portion 84c and the support 83. The second extension portion 84b may extend along the first reverse direction from a middle portion of the coupling portion 84a.

In an embodiment, the pressing portion 84d of the gripper 84 may be disposed between the first extension portion 84c and the second extension portion 84b. The pressing portion 84d may be movably connected to the second extension portion 84b. For example, the pressing portion 84d may move between the first extension portion 84c and the second extension portion 84b toward the first extension portion 84c or toward the second extension portion 84b. The pressing portion 84d may be, for example, connected to an actuator disposed in the second extension portion 84b.

In an embodiment, the gripper 84 may grip the substrate 50 through the pressing portion 84d and the first extension portion 84c. For example, when the pressing portion 84d moves toward the first extension portion 84c, the substrate 50 may contact the first extension portion 84c and the pressing portion 84d. Here, the substrate 50 may be supported between the first extension portion 84c and the pressing portion 84d by the pressure applied by the pressing portion 84d.

In an embodiment, the gripper 84 may also include only the coupling portion 84a and the first extension portion 84c described above. In other words, the second extension portion 84b and the pressing portion 84d can be omitted from the gripper 84 of FIG. 6.

In an embodiment, the first coupling portion 81 of the movable object 80 may be movably coupled to the first rail 61a of the first guide bar 61. The first coupling portion 81 may include a first wheel movably coupled to the first rail 61a. Therefore, the first coupling portion 81 may be moved along the first rail 61a by driving the first wheel.

In an embodiment, the second coupling portion 82 of the movable object 80 may be movably coupled to the second rail 62a of the second guide bar 62. The second coupling portion 82 may include a second wheel movably coupled to the second rail 62a. Therefore, the second coupling portion 82 may be moved along the second rail 62a by driving the second wheel. A center of a rotation axis of the first wheel and a center of a rotation axis of the second wheel may be parallel to each other and may also coincide with each other. A rotation direction of the first wheel and a rotation direction of the second wheel may be the same.

In an embodiment, the first driver 85 of the movable object 80 may be disposed on the support 83 on a side of the support 83. The first driver 85 may be connected to a side of the support 83 and a side of the first coupling portion 81. For example, the first driver 85 may include a first actuator 971 connected to a side of the support 83. The first actuator 971 may be extended (or expanded) and retracted under the control of the first driver 85. The first driver 85 may include a first rotating shaft 981 rotatably connected to a side of the first coupling portion 81. The first driver 85 may be rotated clockwise or counterclockwise by the first rotating shaft 981. The first driver 85 may control the rotation direction of the first wheel of the first coupling portion 81.

In an embodiment, the second driver 86 of the movable object 80 may be disposed on the support 83 on the other side of the support 83. The second driver 86 may be connected to the other side of the support 83 and a side of the second coupling portion 82. For example, the second driver 86 may include a second actuator 972 connected to the other side of the support 83. The second actuator 972 may be extended and retracted under the control of the second driver 86. The second driver 86 may include a second rotating shaft 982 rotatably connected to a side of the second coupling portion 82. The second driver 86 may be rotated clockwise or counterclockwise by the second rotating shaft 982. A center of the second rotating shaft 982 and a center of the first rotating shaft 981 may be parallel to each other and may also coincide with each other. The second driver 86 may control the rotation direction of the second wheel of the second coupling portion 82.

In an embodiment, the support 83 may be moved in a direction away from the first driver 85 and the second driver 86 or may be moved in a direction approaching the first driver 85 and the second driver 86 by the operation of the first actuator 971 of the first driver 85 and the second actuator 972 of the second driver 86. For example, when the first actuator 971 and the second actuator 972 operate in a direction in which they are extended, the support 83 may move in the direction away from the first driver 85 and the second driver 86. On the other hand, when the first actuator 971 and the second actuator 972 operate in a direction in which they are retracted, the support 83 may move in the direction approaching the first driver 85 and the second driver 86. Accordingly, a distance between the support 83 and the bonding stage 40 can be adjusted.

In an embodiment, the support 83 may be rotated clockwise or counterclockwise about the first rotating shaft 981 (or the second rotating shaft 982) by the operation of the first rotating shaft 981 of the first driver 85 and the second rotating shaft 982 of the second driver 86. Accordingly, the support 83 may be rotated clockwise or counterclockwise about the first rotating shaft 981 of the first driver 85 (or the second rotating shaft 982 of the second driver 86).

In an embodiment, the first driving arm 95 may control a tilt angle of the first guide bar 61. The first driving arm 95 may be rotatably connected to the other side of the first coupling portion 81. The first driving arm 95 may include a first link 91 and a second link 92. A side of the first link 91 may be rotatably connected to the first coupling portion 81. For example, a side of the first link 91 may be connected to the first rotating shaft 981 of the first driver 85. The other side of the first link 91 may be rotatably connected to the second link 92. A side of the second link 92 may be connected to a first driving motor.

Although not illustrated, in an embodiment, a second driving arm may be further connected to the other side of the second coupling portion 82 to control a tilt angle of the second guide bar 62. The second driving arm may face the first driving arm 95 described above and may have substantially the same configuration as the first driving arm 95. For example, the second driving arm may be rotatably connected to the second coupling portion 82. The second driving arm may include a third link corresponding to the first link 91 and a fourth link corresponding to the second link 92. A side of the third link may be rotatably connected to the second coupling portion 82. For example, a side of the third link may be connected to the second rotating shaft 982 of the second driver 86. The other side of the third link may be rotatably connected to the fourth link. A side of the fourth link may be connected to a second driving motor.

In an embodiment, the tilt angles of the first guide bar 61 and the second guide bar 62 may be controlled by driving the links of the first driving arm 95 (e.g., the first link 91 and the second link 92) and the links of the second driving arm (e.g., the third link and the fourth link). Accordingly, tilt angles of the support bars 70 connected to the guide bars 61 and 62 may be controlled. In addition, as the tilt angles of the support bars 70 are controlled, a tilt angle of the bonding stage 40 connected to the support bars 70 may be controlled. Consequently, the tilt angle of the bonding stage 40 may be controlled by driving the links of the first driving arm 95 (e.g., the first link 91 and the second link 92) and the links of the second driving arm (e.g., the third link and the fourth link).

The operation of the bonding device 2000 for a display device, according to an embodiment, will be described in detail as follows.

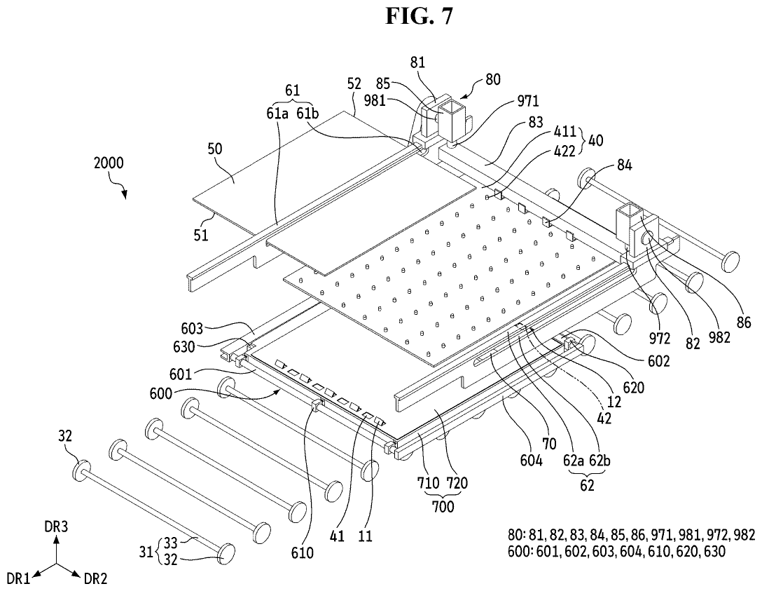

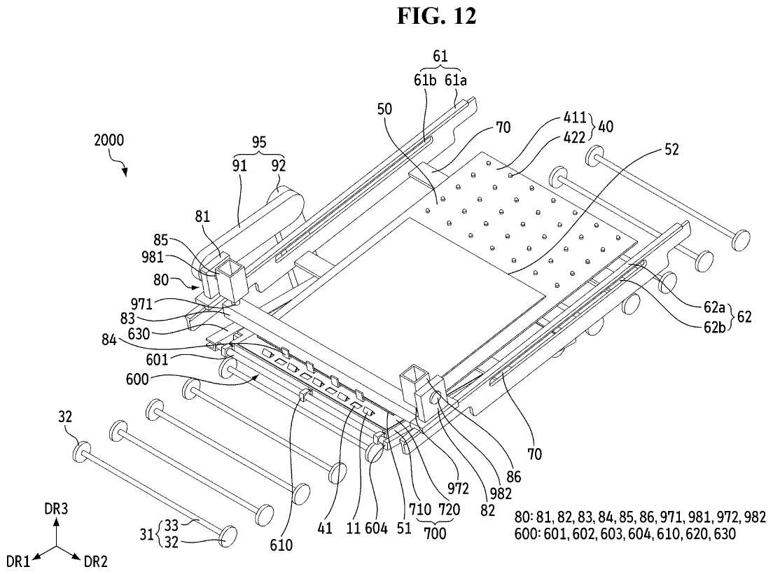

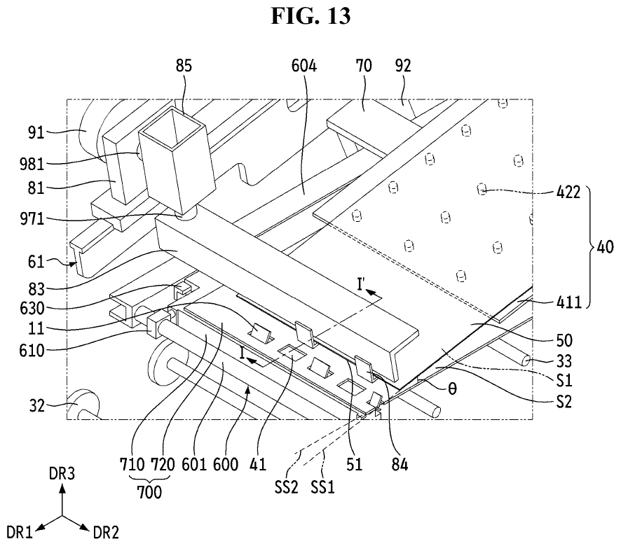

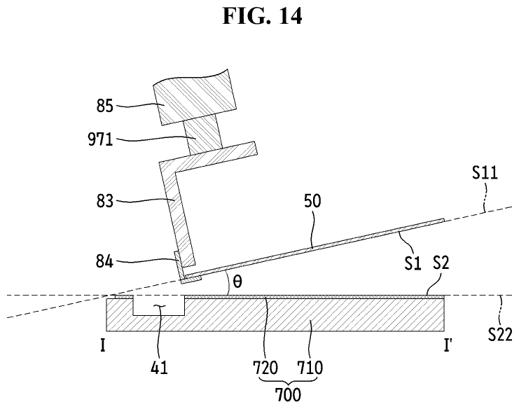

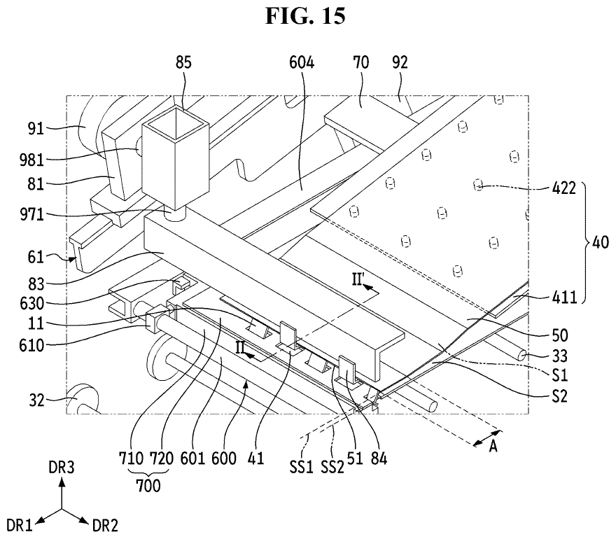

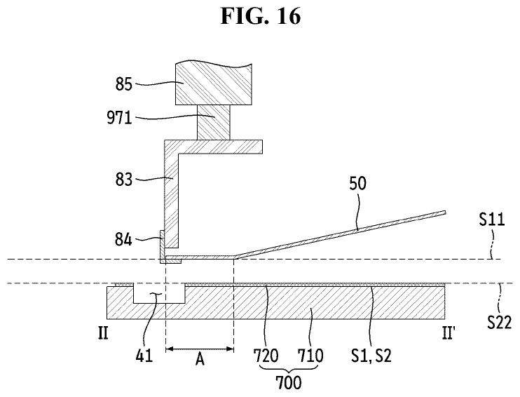

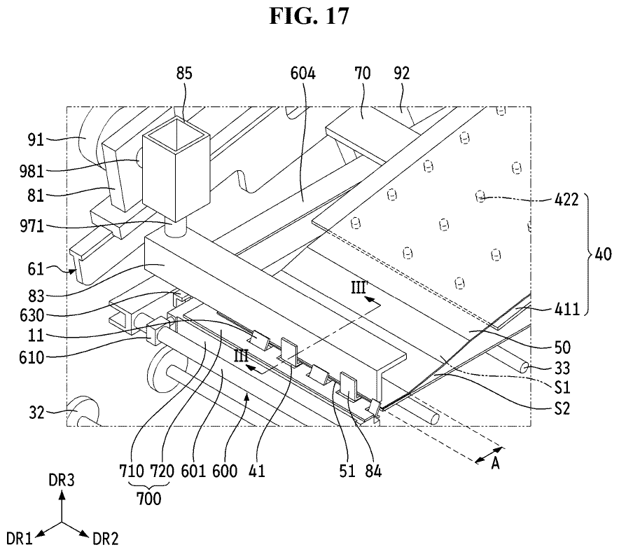

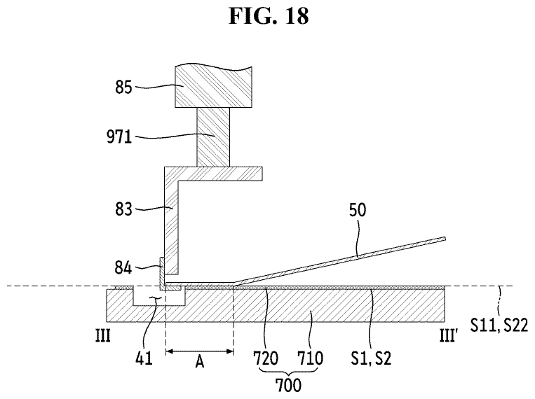

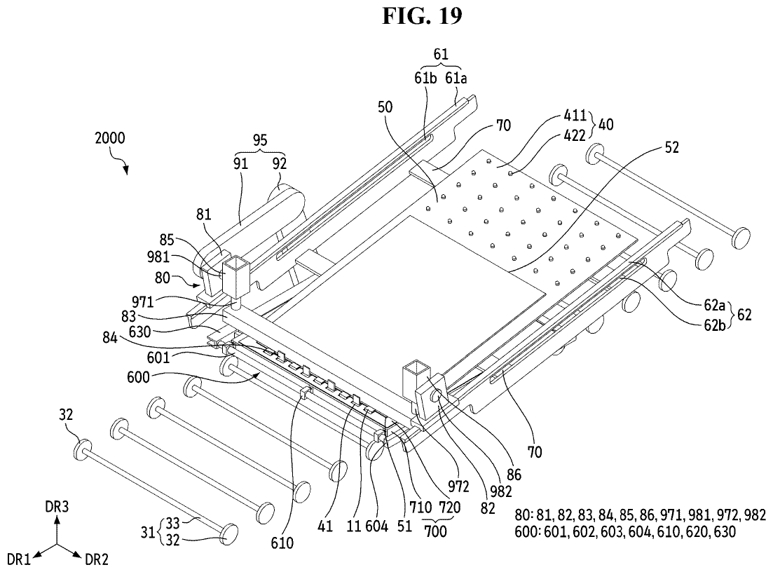

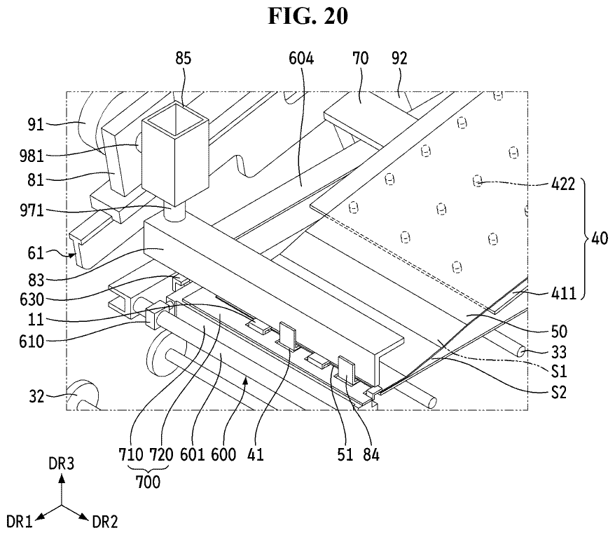

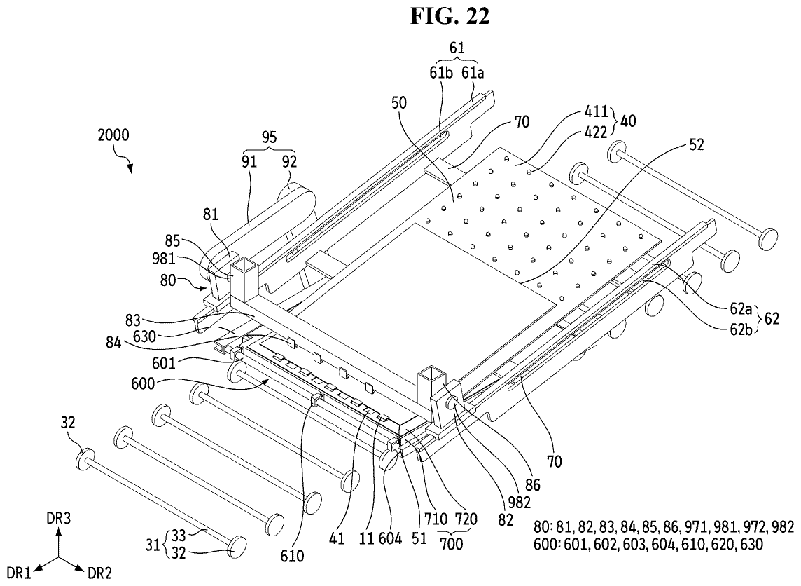

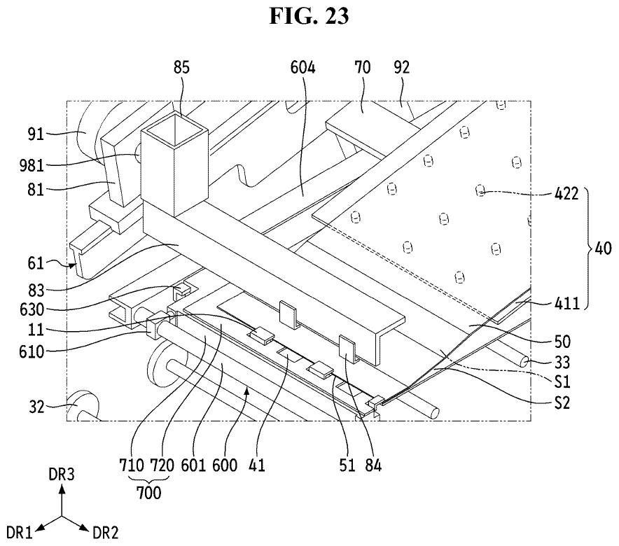

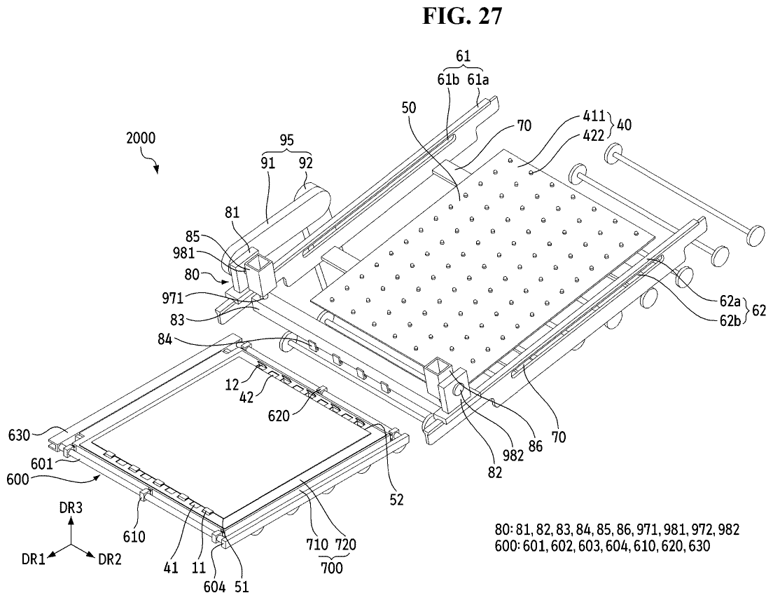

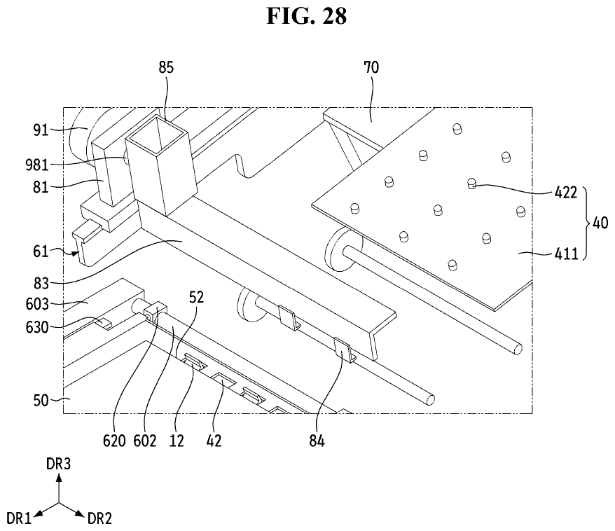

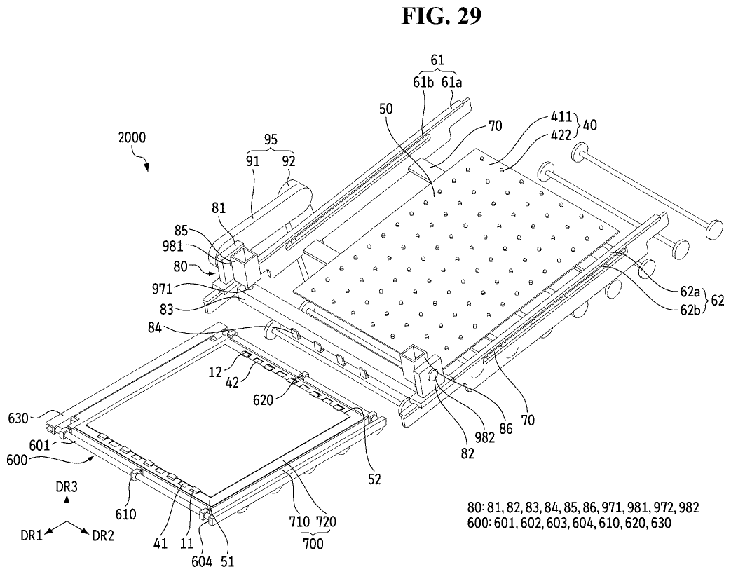

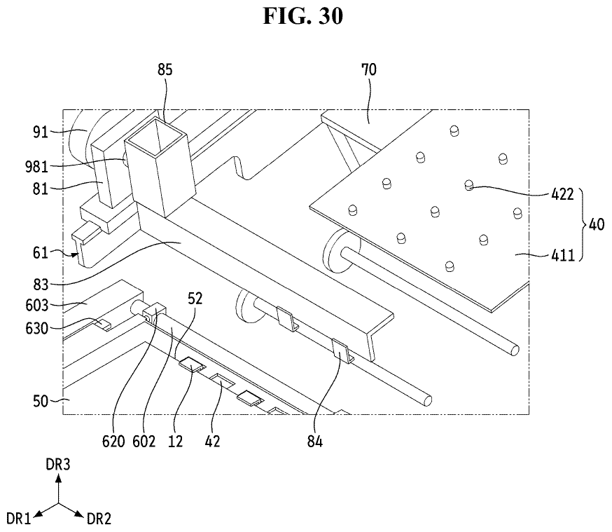

FIGS. 7, 8, 9, 10, 11, 12, 13, 14, 15, 16, 17, 18, 19, 20, 21, 22, 23, 24, 25, 26, 27, 28, 29, and 30 are views for explaining a bonding method using a bonding device for a display device, according to an embodiment. Here, FIG. 13 is an enlarged view of an area around the first clamps and the first holes of FIG. 12, according to an embodiment. FIG. 14 is a cross-sectional view taken along line I-I′ of FIG. 13, according to an embodiment. FIG. 16 is a cross-sectional view taken along line II-II′ of FIG. 15, according to an embodiment. FIG. 18 is a cross-sectional view taken along line III-III' of FIG. 17, according to an embodiment. FIG. 20 is an enlarged view of an area around the first clamps and the first holes of FIG. 19, according to an embodiment. FIG. 23 is an enlarged view of an area around the first clamps and the first holes of FIG. 22, according to an embodiment. FIG. 28 is an enlarged view of an area around the second clamps and the second holes of FIG. 27, according to an embodiment. FIG. 30 is an enlarged view of an area around the second clamps and the second holes of FIG. 29, according to an embodiment.

First, in an embodiment and as illustrated in FIG. 7, the carrier 600 (e.g., the carrier 600 in which the substrate tray 700 is accommodated) may be placed on the transport unit 31 of the bonding device 2000, and the bonding stage 40 may be placed on the carrier 600 to overlap the carrier 600. Here, the movable object 80 may be disposed on each of one end of the first guide bar 61 and the second guide bar 62 so as not to cover a first opening 61b of the first guide bar 61 and a second opening 62b of the second guide bar 62. For example, a transport direction (e.g., the first direction DR1) of the transport unit 31 with respect to the bonding stage 40 may be defined as a downstream direction, and an opposite direction (or a reverse direction) of the transport direction of the transport unit 31 may be defined as an upstream direction. In this case, the movable object 80 may be disposed at one end of each of the first guide bar 61 and the second guide bar 62 in the upstream direction. In such case, the movable object 80 may not overlap the bonding stage 40 or may overlap an edge of the bonding stage 40.

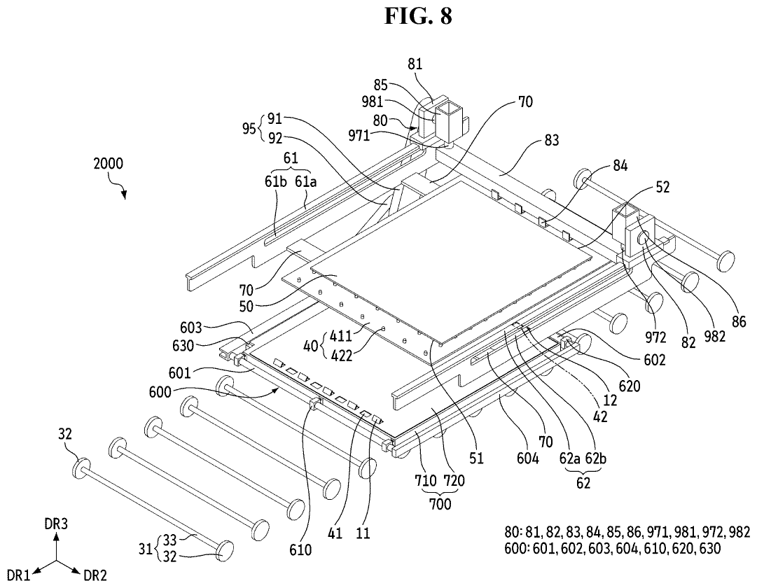

Next, in an embodiment and as illustrated in FIGS. 7 and 8, a substrate 50 may be loaded onto the bonding device 2000 from outside. For example, the substrate 50 supported by a robot arm may be loaded onto the bonding device 2000. As a specific example, the robot arm may include a plurality of fingers spaced apart from each other. The substrate 50 placed on the fingers may be loaded onto the bonding device 2000 together with the fingers. For example, the fingers on which the substrate 50 is placed may pass through the first opening 61b of the first guide bar 61 to be disposed between the first guide bar 61 and the second guide bar 62. Accordingly, the bonding stage 40 may be disposed on the lower portion of the fingers to overlap the fingers, and a carrier 600 (e.g., the carrier 600 on which the substrate tray 700 is mounted) may be disposed on the lower portion of the bonding stage 40 to overlap the bonding stage 40. In other words, the fingers may be disposed between the bonding stage 40 and the substrate 50, between the first guide bar 61 and the second guide bar 62, the bonding stage 40 may be disposed between the fingers and the carrier 600 and the carrier 600 may be disposed between the bonding stage 40 and the transport unit 31. Here, the bonding stage 40 may be maintained in a horizontal position. For example, the bonding stage 40 and the carrier 600 (or the substrate tray 700 accommodated in the carrier 600) may be disposed to be parallel to each other. Meanwhile, the fingers may be disposed on the bonding stage 40 so as not to overlap support pins 422 of the bonding stage 40.

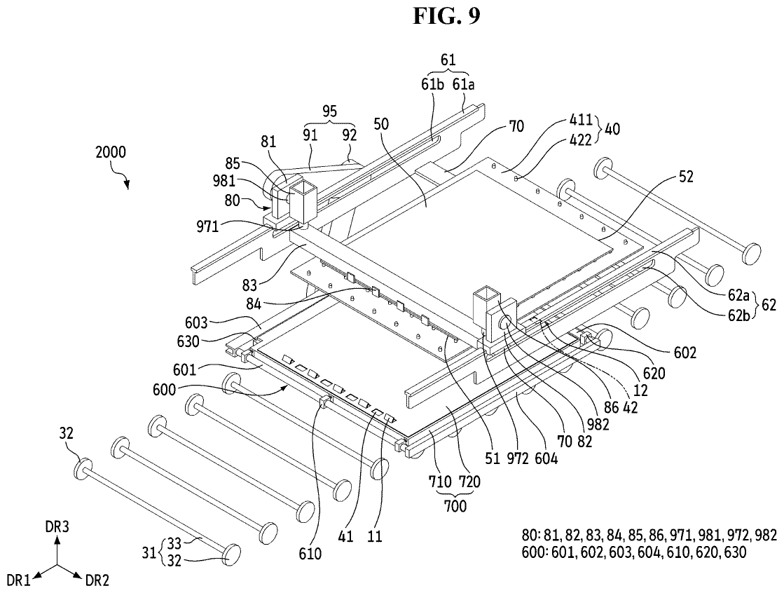

Thereafter, in an embodiment, the fingers may be lowered toward the bonding stage 40, where the lowered fingers may be disposed between the support pins 422 of the bonding stage 40. As the fingers are lowered, the substrate 50 placed on the fingers may be supported by the support pins 422. In other words, as the fingers are lowered, the substrate 50 may be supported only by the support pins 422 instead of the fingers. Here, as illustrated in FIG. 9, the lower surface of the substrate 50 may be in contact with the balls of the support pins 422.

Next, in an embodiment, the fingers that delivered the substrate 50 may be discharged to the outside through the first opening 61b.

Thereafter, in an embodiment and as illustrated in FIG. 9, the movable object 80 may move in the downstream direction (e.g., the first direction DR1) along each of the first guide bar 61 and the second guide bar 62 to be disposed adjacent to a first side 51 (or an edge) of the substrate 50 on the bonding stage 40.

Next, in an embodiment, the movable object 80 may be moved so that grippers 84 of the movable object 80 are disposed between the bonding stage 40 and the substrate 50. Here, the grippers 84 may support the lower surface (e.g., the lower surface of the first side 51 of the substrate 50) of the substrate 50 between the support pins 422. For example, the grippers 84 may support the lower surface (e.g., the lower surface of the first side 51 of the substrate 50) of the substrate 50 at one edge of the bonding stage 40. In this state, the gripper 84 may grip the first side 51 of the substrate 50. Meanwhile, in another embodiment, the gripper 84 may not grip and may only support the first side 51 of the substrate 50.

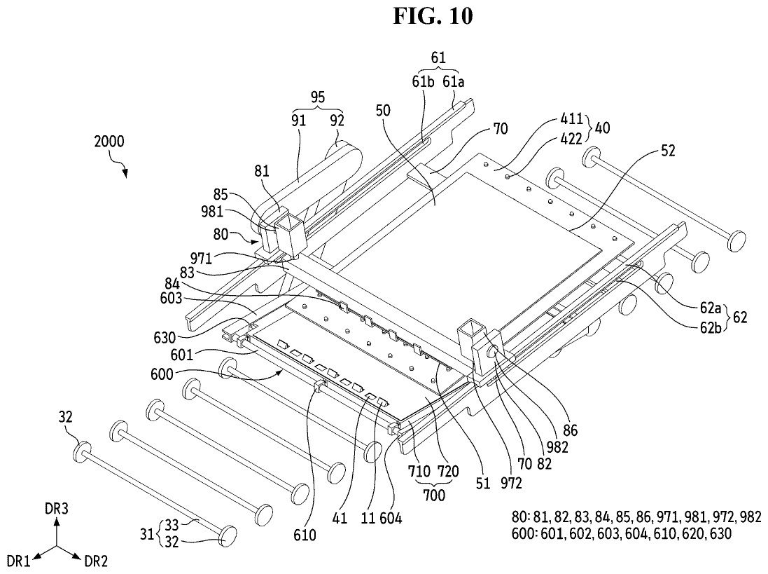

Thereafter, in an embodiment and as illustrated in FIG. 10, the bonding stage 40 may be rotated in a state where the first side 51 of the substrate 51 is supported by the grippers 84. For example, in the state where the first side 51 of the substrate 51 is supported by the grippers 84, the bonding stage 40 may be tilted. For example, as the first guide bar 61 and the second guide bar 62 are tilted under the control of a first driving arm 95 and a second driving arm, the bonding stage 40 may be tilted toward the downstream direction. Specifically, the bonding stage 40 may be tilted in a predetermined angle so that the upper surface (e.g., a surface where the support pins 422 are disposed) of the bonding stage 40 faces the downstream direction of the transport unit 31 and so that the lower surface (e.g., the opposite surface of the upper surface of the bonding stage 40) of the bonding stage 40 faces the upstream direction of the transport unit 31. Here, an angle formed between the tilted upper surface of the bonding stage 40 and the transport unit 31 in the downstream direction may be an obtuse angle. In addition, an angle formed between the tilted lower surface of the bonding stage 40 and the transport unit 31 in the upstream direction may be an acute angle.

Subsequently, in an embodiment and as illustrated in FIGS. 11 to 14, the movable object 80 may move in the downstream direction along each of the first guide bar 61 and the second guide bar 62 tilted toward the downstream direction, and, at the same time, the carrier 600 may also move along the downstream direction on the transport unit 31. At this time, the substrate 50 on the support pins 422 may also be moved in the downstream direction along the tilted surface of the bonding stage 40 together with the movable object 80. For example, the substrate 50 may be moved along the downstream direction together with the movable object 80 while being supported (and/or gripped) by the grippers 84 of the movable object 80. Here, since the movable object 80 moves in the downstream direction along the tilted first guide bar 61 and the second guide bar 62 while the carrier 600 moves along the transport unit 31 in a non-inclined horizontal state, the grippers 84 of the movable object 80 may gradually approach the first holes 41 disposed in the substrate tray 700 of the carrier 600 as the movable object 80 and the carrier 600 moves along the downstream direction.

In an embodiment and as illustrated in FIGS. 12 to 14, when the grippers 84 of the movable object 80 approaches the first holes 41 of the substrate tray 700, the movement of the movable object 80 and the carrier 600 may be stopped. As illustrated in FIGS. 13 to 14, the substrate 50 may be supported by the grippers 84 and the bonding stage 40 and placed on an electrostatic chuck 720. For example, as illustrated in FIGS. 13 and 14, the substrate 50 and the electrostatic chuck 720 may be spaced apart from each other by a predetermined distance in the third direction DR3 so as not to be in contact with each other, and a portion of the substrate 50 (e.g., a portion of the first side 51 of the substrate 50) may overlap a portion of the electrostatic chuck 720 above the electrostatic chuck 720. Here, as illustrated in FIGS. 13 and 14, an angle θ formed by the substrate 50 and the electrostatic chuck 720 near the first side 51 of the substrate 50 may be an acute angle. For example, the angle θ formed by opposing surfaces of the substrate 50 and the electrostatic chuck 720 near the first side 51 of the substrate 50 may be an acute angle. Specifically, when one surface of the substrate 50 facing the electrostatic chuck 720 is defined as the first surface S1 and one surface of the electrostatic chuck 720 facing the first surface S1 is defined as a second surface S2, the angle θ formed between the first surface S1 of the substrate 50 and the second surface S2 of the electrostatic chuck 720 near the first side 51 of the substrate 50 may be an acute angle. In other words, near the first side 51 of the substrate 50, the angle θ formed between a virtual first extension surface SS1 extending along the first surface S1 of the substrate 50 and a virtual second extension surface SS2 extending along the second surface S2 of the electrostatic chuck 720 may be an acute angle.

Thereafter, in an embodiment and as illustrated in FIGS. 15 and 16, the first driver 85 and the second driver 86 may be rotated by a predetermined angle toward the downstream direction. Accordingly, the support 83 and the grippers 84 attached to the support 83 may be rotated by a predetermined angle toward the downstream direction. For example, the support 83 and the grippers 84 attached to the support 83 may be rotated by a predetermined angle toward the downstream direction so that the horizontal portion 83a of the support 83 and the upper surface (e.g., the tilted surface) of the bonding stage 40 are not parallel. Then, the grippers 84 may overlap the first holes 41, respectively, on the first holes 41. In addition, as the substrate 50 moves along the downstream direction by a predetermined distance through the rotation of the grippers 84, the first side 51 of the substrate 50 and the first holes 41 may be overlapped. At this time, as illustrated in FIG. 16, the substrate 50 may be supported by the grippers 84 and the bonding stage 40 to be disposed on the electrostatic chuck 720. For example, as illustrated in FIG. 16, the substrate 50 and the electrostatic chuck 720 may be spaced apart from each other by a predetermined distance to not be in contact with each other, and a portion of the substrate 50 (e.g., a portion of the substrate 50 including the first side 51) may overlap a portion of the electrostatic chuck 720 on the electrostatic chuck 720. Here, the first side 51 of the substrate 50 and the portion disposed adjacent to the first side 51 may be disposed to be parallel to the electrostatic chuck 720 through the rotation of the grippers 84. For example, when the first side 51 and the portion disposed adjacent to the first side 51 of the substrate 50 are defined, an outer portion A, a surface S1 of the substrate 50 and a surface S2 of the electrostatic chuck 720 facing each other may be directed parallel to each other in the outer portion A of the substrate 50. Specifically, a first surface S1 of the substrate 50 and a second surface S2 of the electrostatic chuck 720 in the outer portion A of the substrate 50 may be parallel to each other. In other words, an imaginary first extension surface SS1 extended along the first surface S1 of the substrate 50 and an imaginary second extension surface SS2 extended along the second surface S2 of the electrostatic chuck 720 in the outer portion A of the substrate 50 may be directed parallel to each other. Meanwhile, according to the rotation angle of the grippers 84 in the FIGS. 15 and 16, the substrate 50 in the outer portion A of the substrate may have a curved shape rather than a straight line. For example, the substrate 50 in the outer edge A of the substrate may have a parabolic shape that is convex toward the electrostatic chuck 720.

Next, in an embodiment and as illustrated in FIGS. 17 and 18, a first actuator 971 and a second actuator 972 may extend the substrate 50 toward a substrate tray 700 by a predetermined distance. Accordingly, the support 83 connected to the first actuator 971 and the second actuator 972, and the grippers 84 connected to the support 83 may be lowered toward the electrostatic chuck 720 of the substrate tray 700. At this time, the grippers 84 may be inserted respectively into the first holes 41. For example, in each space of the first holes 41, the grippers 84 may be inserted respectively into the first holes 41 in a state of being concentrated toward the upstream direction. Here, since the size of the first hole 41 in the first direction DR1 is larger than the size of the gripper 84 in the first direction DR1, when the grippers 84 are inserted into the first holes 41, respectively, there may be a free space (or gap) between each gripper 84 and each first hole 41. For example, when the grippers 84 are inserted into the first holes 41, there may be a free space in each first hole 41 so that the grippers 84 can move further in the downstream direction. At this time, as the grippers 84 are inserted into the first holes 41, a portion of the substrate 50 (e.g., the outer portion A of the substrate 50) may be in contact with the electrostatic chuck 720 of the substrate tray 700 first. According to an embodiment, upon initial contact between the substrate 50 and the electrostatic chuck 720, the outer portion A of the substrate 50 and the electrostatic chuck 720 may be in face-to-face contact. For example, as illustrated in FIGS. 15 and 16, this is because the surface S1 of the substrate 50 and the surface S2 of the electrostatic chuck 720 facing each other in the outer portion A of the substrate 50 are disposed to be parallel to each other. Accordingly, the first side 51 of the substrate 50 and the electrostatic chuck 720 may be prevented from making line-to-face contact with the substrate 50 forming a predetermined angle (e.g., θ) with the electrostatic chuck 720. Therefore, according to an embodiment, damage to the substrate 50 when the substrate 50 initially contacts the electrostatic chuck 720 (e.g., line-to-face contact) may be prevented, and in addition, at the time of the initial contact between the substrate 50 and the electrostatic chuck 720, the contact area between the substrate 50 and the electrostatic chuck 720 may increases, thereby improving the adhesion force (or bonding force) between the substrate 50 and the electrostatic chuck 720. Further, the alignment of the substrate 50 on the substrate tray 700 may be improved.

In an embodiment, when the gripper 84 is gripping the substrate 50, the gripped state of the substate 50 by the gripper 84 may be released first when the grippers 84 of the movable object 80 are inserted into the first holes 41.

Subsequently, in an embodiment and as illustrated in FIGS. 19 and 20, the substrate 50 may be clamped as first clamps 11 are rotated toward the upper surface of the substrate 50. Accordingly, the first side 51 of the substrate 50 and the periphery thereof may be supported and fixed by the first clamps 11.

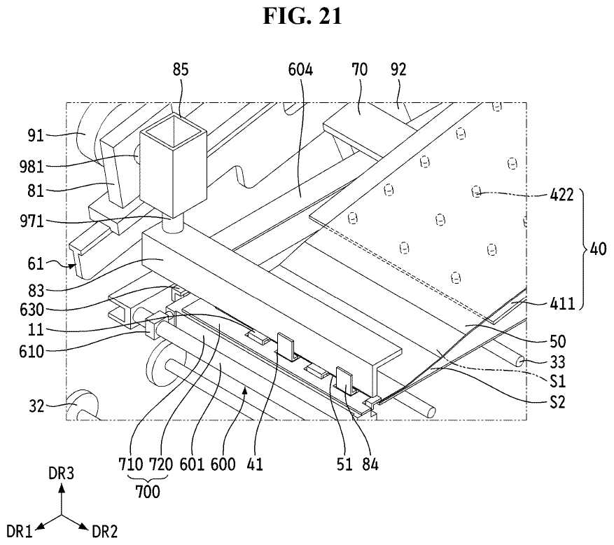

Thereafter, in an embodiment and as illustrated in FIG. 21, with the grippers 84 inserted into the first holes 41, the movable object 80 may be moved by a predetermined distance toward the downstream direction and then stopped. Then, the grippers 84 may be moved to the free space of the first holes 41, respectively, along the downstream direction. Accordingly, as the grippers 84 move away from the first side 51 of the substrate 50, the contact between the first side 51 of the substrate 50 and the grippers 84 may be released. In other words, the first side 51 (or the outer portion A) of the substrate 50 is not supported by the grippers 84 and may be supported by the first clamps 11. At this time, the first clamps 11 may serve as stoppers that prevent the substrate 50 from moving in the downstream direction.

According to an embodiment, the grippers 84 and the first clamps 11 may support the substrate 50 together for a certain period of time. For example, as illustrated in FIG. 18, in a state where the grippers 84 support the substrate 50, the first clamp 11 may clamp the substrate 50. In other words, the first side 51 of the substrate 50 and the outer portion A of the substrate 50 may be simultaneously supported by the grippers 84 and the first clamps 11 for a certain period of time. However, after the above-described certain period of time, the grippers 84 may be released from supporting the substrate 50, while the first clamp 11 may be maintained supporting the substrate 50. In this way, since the time during which the first side 51 of the substrate 50 and the outer portion A of the substrate 50 are supported by the grippers 84 and the time when the first side 51 of the substrate 50 and the outer portion A of the substrate 50 are supported by the first clamps 11 overlap for a certain period of time, the position of the substrate 50 may not be distorted during the clamping operation by the first clamps 11 and be constantly maintained.

Accordingly, in an embodiment, when the means supporting the substrate 50 is transformed from the grippers 84 to the first clamps 11, the alignment state of the substrate 50 on the electrostatic chuck 720 may be improved.

Meanwhile, in an embodiment, in order to minimize damage to the substrate 50 due to friction between the substrate 50 and the gripper 84 due to horizontal movement of the gripper 84 supporting the substrate 50, the movable object 80 may descend further toward the hole 41 before the movable object 80 moves by a predetermined distance along the downstream direction. For example, in FIG. 18, the gripper 84 may further descend along the third reverse direction, then move in the downstream direction (e.g., the first direction DR1) as illustrated in FIG. 21.

Next, in an embodiment and as illustrated in FIGS. 22 and 23, in a state where the first side 51 of the substrate 50 is supported and fixed by the first clamps 11, the movable object 80 may be raised along the third direction DR3 so as to move away from the first holes 41. Accordingly, the grippers 84 may be raised after being exposed to the outside within the first holes 41. Accordingly, the grippers 84 may be disposed above the substrate 50 so as not to be in contact with the substrate 50.

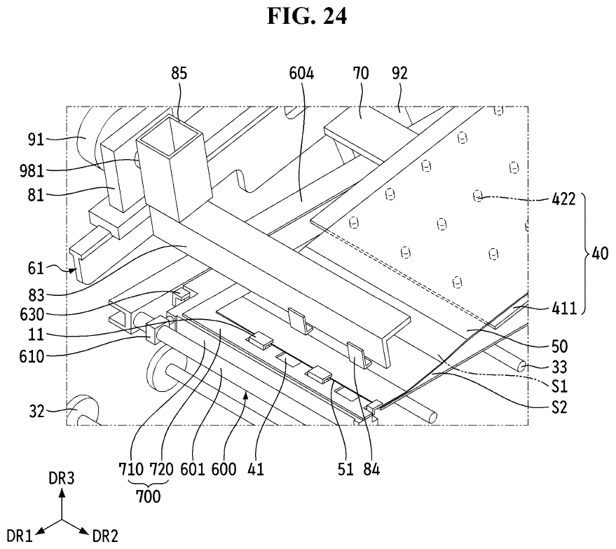

Subsequently, in an embodiment and as illustrated in FIG. 24, the first driver 85 and the second driver 86 may be rotated by a predetermined angle toward the upstream direction. Accordingly, the support 83 and the grippers 84 attached to the support 83 may be rotated by a predetermined angle toward the upstream direction. For example, the support 83 and the grippers 84 attached to the support 83 may be rotated by a predetermined angle toward the upstream direction so that the horizontal portion 83a of the support 83 and the upper surface (e.g., the tilted surface) of the bonding stage 40 are parallel.

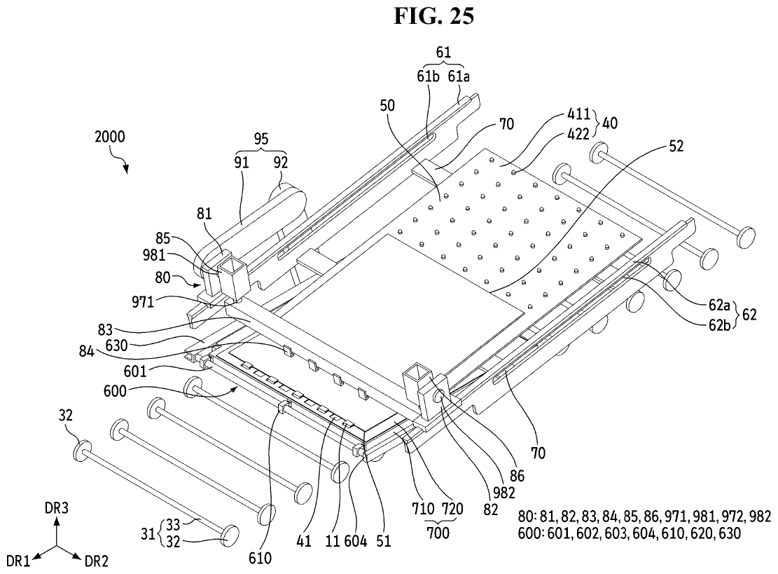

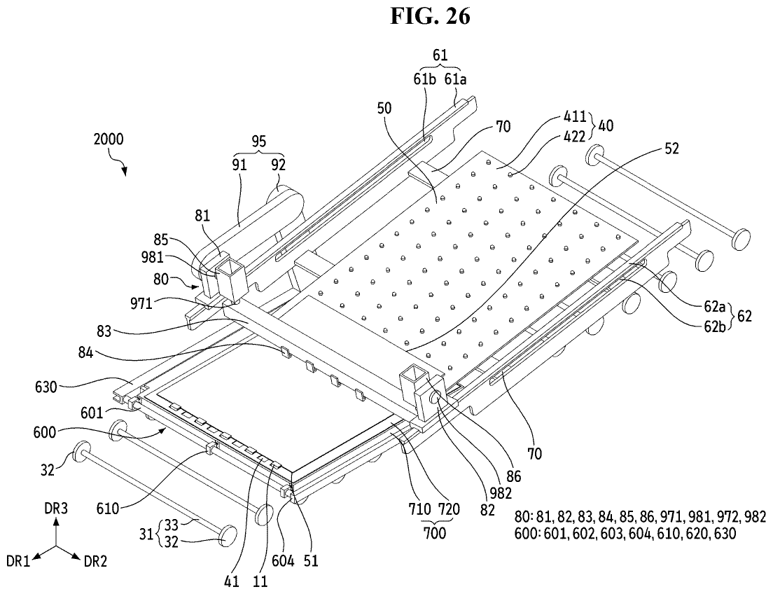

Thereafter, in an embodiment and as illustrated in FIGS. 25 and 26, in a state where the first side 51 of the substrate 50 is supported and fixed by the first clamps 11, the carrier 600 may move along the downstream direction. In other words, in a state where the bonding stage 40 is stopped, the carrier 600 may move further along the downstream direction. Then, the electrostatic chuck 720 of the substrate tray 700, which was covered by the bonding stage 40, may be gradually exposed, and the substrate 50 clamped by the first clamps 11 of the substrate tray 700 may gradually be moved in the downstream direction together with the substrate tray 700. Accordingly, the remaining portion of the substrate 50 of the bonding stage 40 may gradually be in contact with the electrostatic chuck 720. In other words, the substrate tray 700 may be moved in the downstream direction by the movement of the carrier 600, and due to the movement of the substrate tray 700, the substrate tray 700 may pull down the substrate 50 from the bonding stage 40 (e.g., the bonding stage 40 tilted toward the downstream side) in a state of gripping the first side 51 of the substrate 50 on the bonding stage 40. Accordingly, as the carrier 600 (or the substrate tray 700 of the carrier 600) moves along the downstream direction, the contact area between the bonding stage 40 (e.g., the support pins 422 of the bonding stage 40) and the substrate 50 may become gradually smaller while the contact area between the electrostatic chuck 720 of the substrate tray 700 accommodated in the carrier 600 and the substrate 50 may become gradually larger. Therefore, the substrate 50 on the bonding stage 40 may be moved from the bonding stage 40 onto the electrostatic chuck 720 of the substrate tray 700 while moving along the downstream direction.

Thereafter, in an embodiment and as illustrated in FIGS. 27 and 28, the carrier 600 may be moved further along the downstream direction to the extent that the carrier 600 and the bonding stage 40 no longer overlap each other. Then, the substrate 50 may be completely moved from the bonding stage 40 onto the electrostatic chuck 720 of the substrate tray 700. In this way, as the carrier 600 moves along the downstream direction, the first side 51 of the substrate 50 that is closer to the downstream direction may begin to contact the electrostatic chuck 720, and then a second side 52 of the substrate 50 may lastly contact the electrostatic chuck 720. At this time, the second side 52 of the substrate 50 on the electrostatic chuck 720 may be adjacently disposed to second holes 42 and second clamps 12 of the substrate tray 700.

Subsequently, in an embodiment and as illustrated in FIGS. 29 and 30, the substrate 50 may be clamped as the second clamps 12 rotate toward the upper surface of the substrate 50. Accordingly, the second side 52 of the substrate 50 and the periphery thereof may be supported and fixed by the second clamps 12. Accordingly, the substrate 50 may be supported and fixed on the electrostatic chuck 720 by the first clamps 11 and the second clamps 12.

Next, in an embodiment, the carrier 600 in which the substrate tray 700 (e.g., the substrate tray 700 in which the substrate 50 is disposed) is accommodated may move further along the transport unit 31 in the downstream direction (e.g., the first direction) and be loaded onto a position changing device.

In an embodiment, the position changing device may change the position of the carrier 600. For example, after the above-described bonding process between the substrate 50 and the substrate tray 700, the position changing device may change the position of the carrier 600 transported along the transport unit 31 from the horizontal position to the vertical position, as in the example illustrated in FIG. 4. Meanwhile, in the position changing device, an electrostatic power may be provided from the electrostatic chuck 720 and the substrate 50 may be attached to the electrostatic chuck 720.

Thereafter, in an embodiment, the carrier 600 disposed in a vertical position (e.g., the carrier 600 in a vertical position including a transport tray and a substrate 50) may be moved along the transport unit 31 and loaded onto the bonding device 1000 described above. For example, the carrier 600 in a vertical position may be moved along the transport unit 31 to be loaded inside a chamber 100 through a first gate G1 of the chamber 100 of FIG. 1. Inside the chamber 100, a deposition process in respect to the substrate 50 accommodated in the carrier 600 in a vertical position may be processed. At this time, inside the chamber 100, a deposition material may be provided while the substrate 50 is maintained in a vertical position.

The display device, according to an embodiment, can be applied to various electronic devices. The electronic device, according to an embodiment, includes the display device described above and may further include modules or devices having additional functions in addition to the display device.

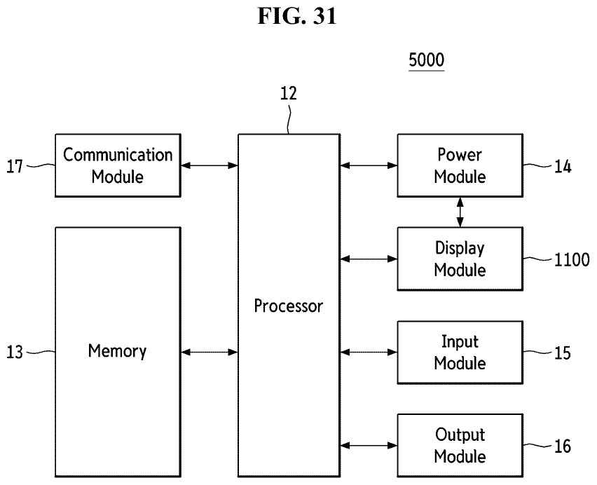

FIG. 31 is a block diagram of an electronic device, according to an embodiment. Referring to FIG. 31, the electronic device 5000, according to an embodiment, may include a display module (1100, e.g., a display device), a processor 12, a memory 13, and a power module 14. The electronic device 5000 may further include an input module 15, a non-image output module 16 and/or a communication module 17.

In an embodiment, the electronic device 5000 may output various information in the form of images through the display module 1000. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 1100. The non-image output module 16 may receive information other than images transmitted from the processor 12, such as sound, haptics, and light, and provide the information to the user. The communication module 17 is a module that is responsible for transmitting and receiving information between the electronic device 5000 and an external device, and may include a receiving unit and a transmitting unit.

At least one of the components of the electronic device 5000 described above may be included in the display device, according to the embodiments described above. In addition, some of the individual modules functionally included in one module may be included in the display device, and others may be provided separately from the display device. For example, the display device includes a display module 1100, and the processor 12, memory 13, and power module 14 may be provided in the form of other devices within the electronic device 11 other than the display device.

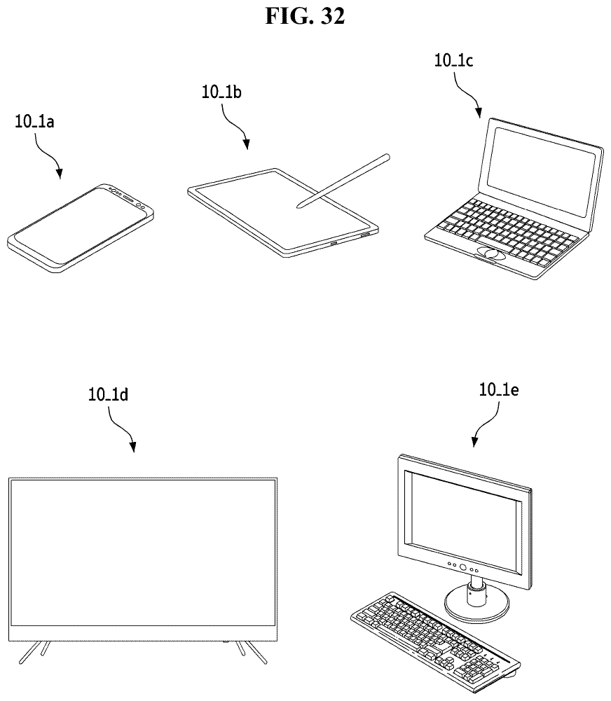

FIGS. 32, 33, and 34 are graphical images of electronic devices according to various embodiments. FIGS. 32 to 34 illustrate examples of various electronic devices to which the display device, according to embodiments, is applied.

In an embodiment, FIG. 32 illustrates a smartphone 10_1a, a tablet PC 10_1b, a laptop 10_1c, a TV 10_1d, and a desk monitor 10_1e as examples of electronic devices.

In an embodiment, in addition to the display module 1000, the smartphone 10_1a may include an input module such as a touch sensor and a communication module. The smartphone 10_1a may process information received through the communication module or other input modules and display the information through the display module of the display device.

In an embodiment, in the case of tablet PCs 10_1b, laptops 10_1c, TVs 10_1d, and desk monitors 10_1e, they also include display modules and input modules similar to smartphones 10_1, and may additionally include communication modules in some cases.

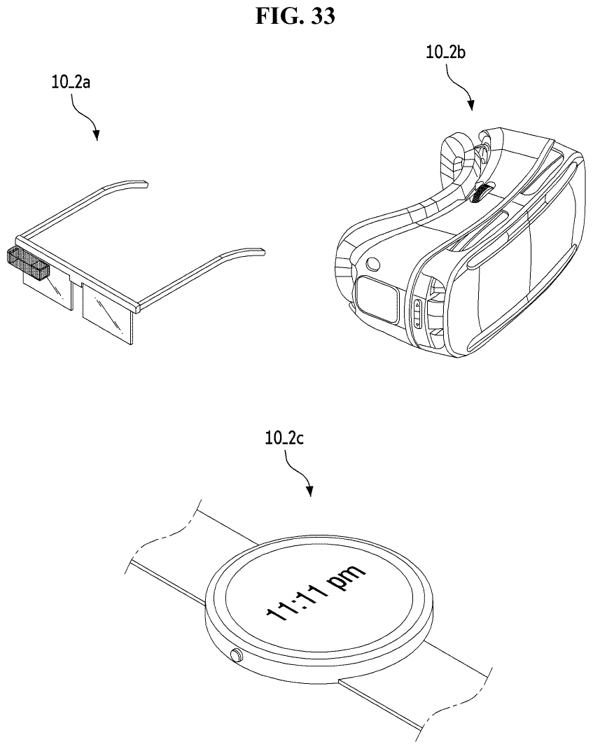

FIG. 33 shows embodiments of an electronic device including a display module being applied to a wearable electronic device, where the wearable electronic device may be a smart glasses 10_2a, a head-mounted display 10_2b, a smart watch 10_2c, etc.

In an embodiment, the smart glasses 10_2a and the head-mounted display 10_2b may include a display module that emits a display image and a reflector that reflects the emitted display screen and provides it to the user's eyes, thereby providing a virtual reality or augmented reality screen to the user.

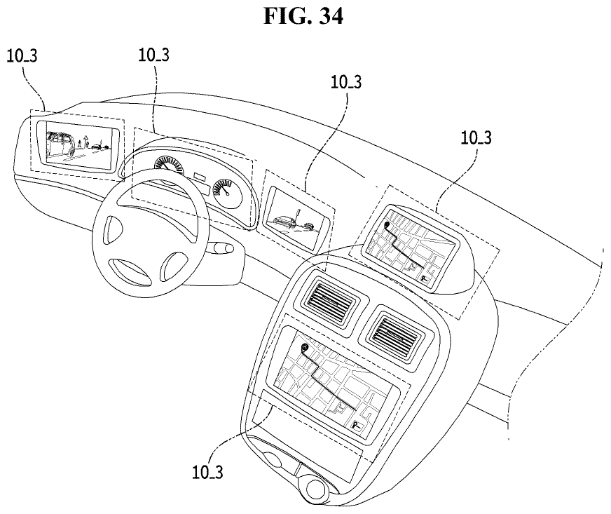

In an embodiment, the smart watch 10_2c includes a biometric sensor as an input device, and may provide biometric information recognized by the biometric sensor to the user through the display module. FIG. 34 illustrates a case where an electronic device including a display module is applied to a vehicle. For example, in an embodiment, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the invention without departing from the scope and spirit of the invention. As such, the disclosed embodiments of the invention are used in a generic and descriptive sense only and not for purposes of limitation. Thus, it will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A bonding device for a display device, the bonding device comprising:
a transport unit;
a carrier, wherein the carrier is movable on and along the transport unit and includes a substrate tray accommodated therein;
a rotatable bonding stage disposed on the transport unit;
a support disposed on the bonding stage, wherein the support is movable on the bonding stage along an upstream direction of the transport unit, a downstream direction of the transport unit, a downward direction toward the bonding stage, an upward direction opposite to the downward direction, a first rotation direction toward the upstream direction, and a second rotation direction toward the downstream direction; and
a gripper connected to the support, wherein the gripper is disposed between the support and the bonding stage.

2. The bonding device of claim 1,
wherein the support has an “r” shaped cross section.

3. The bonding device of claim 1,
wherein the support has an “L” shaped cross section.

4. The bonding device of claim 2,
wherein the bonding stage comprises:
a base plate disposed on the transport unit; and
a support pin disposed on the base plate.

5. The bonding device of claim 1, further comprising:
a first driver connected to one side of the support; and
a second driver connected to an other side of the support.

6. The bonding device of claim 5,
wherein the first driver comprises a first actuator connected to the one side of the support, and
the second driver comprises a second actuator connected to the other side of the support.

7. The bonding device of claim 5, further comprising:
a first guide bar disposed on the one side of the support; and
a second guide bar disposed on the other side of the support.

8. The bonding device of claim 7, further comprising:
a first coupling portion connected to the first guide bar, wherein the first coupling portion is movable along the first guide bar; and
a second coupling portion connected to the second guide bar, wherein the second coupling portion is movable along the second guide bar.

9. The bonding device of claim 8,
wherein the first driver is rotatably coupled to the first coupling portion, and
the second driver is rotatably coupled to the second coupling portion.

10. The bonding device of claim 9, further comprising:
a first driving arm rotatably connected to the first coupling portion; and
a second driving arm rotatably connected to the second coupling portion.

11. The bonding device of claim 8,
wherein the first guide bar comprises:
a first rail connected to the first coupling portion; and
a first opening extending along the first rail.

12. The bonding device of claim 11,
wherein the second guide bar comprises:
a second rail connected to the second coupling portion; and
a second opening extending along the second rail.

13. The bonding device of claim 7,
further comprising a support bar disposed between the first guide bar and the second guide bar and between the transport unit and the bonding stage.

14. The bonding device of claim 13,
wherein the support bar is connected to the first guide bar, the second guide bar, and the bonding stage.

15. The bonding device of claim 1,
wherein the substrate tray comprises: an electrostatic chuck; a first clamp disposed at an edge of the electrostatic chuck; a first hole disposed adjacent to the first clamp; a second clamp disposed at an other edge of the electrostatic chuck; and a second hole disposed adjacent to the second clamp,
wherein the gripper is disposed to correspond to the first hole of the substrate tray.

16. The bonding device of claim 1,
wherein the bonding stage is rotatable at a predetermined angle so that an upper surface of the bonding stage faces the downstream direction of the transport unit and that a lower surface of the bonding stage faces the upstream direction of the transport unit.

17. A bonding method for a display device, the bonding method comprising:
preparing a bonding device for the display device, wherein the bonding device comprises a transport unit, a carrier movable on and along the transport unit and having a substrate tray accommodated therein, a rotatable bonding stage disposed on the transport unit, a support disposed on the bonding stage and movable on the bonding stage along an upstream direction of the transport unit, a downstream direction of the transport unit, a downward direction toward the bonding stage, an upward direction opposite to the downward direction, a first rotation direction toward the upstream direction, and a second rotation direction toward the downstream direction, and a gripper connected to the support to be disposed between the support and the bonding stage,
placing the carrier on the transport unit;
placing the bonding stage to be parallel to the transport unit;
placing a substrate on an upper surface of the bonding stage;
supporting a first side of the substrate in the downstream direction using the gripper;
rotating the bonding stage so that an upper surface of the bonding stage faces the downstream direction;
moving the support and the carrier to the downstream direction in a state where the substrate is supported by the gripper;
moving the support so that the gripper is disposed adjacent to a first hole of the substrate tray; and
rotating the support in the second rotation direction in a state where the gripper is disposed adjacent to the first hole of the substrate tray.

18. The bonding method of claim 17,
wherein the rotating the support in the second rotation direction comprises rotating the support in the second rotation direction so that an outer portion of the substrate supported by the gripper and an electrostatic chuck of the substrate tray are directed parallel to each other.

19. The bonding method of claim 17,
further comprising moving the support in the downward direction so that the gripper supporting the substrate is inserted into the first hole.

20. An electronic device comprising:
a display device, and
a bonding device for bonding the display device, wherein the bonding device includes:
a transport unit;
a carrier, wherein the carrier is movable on and along the transport unit and includes a substrate tray accommodated therein;
a rotatable bonding stage disposed on the transport unit;
a support disposed on the bonding stage, wherein the support is movable on the bonding stage along an upstream direction of the transport unit, a downstream direction of the transport unit, a downward direction toward the bonding stage, an upward direction opposite to the downward direction, a first rotation direction toward the upstream direction, and a second rotation direction toward the downstream direction; and
a gripper connected to the support to be disposed between the support and the bonding stage.
